(19) United States
(12) Patent Application Publication
(10) Pub. No.: US 2025/0386546 A1
(43) Pub. Date: Dec. 18, 2025

(54) SEMICONDUCTOR DEVICE

(71) Applicant: SAMSUNG ELECTRONICS CO., LTD., SUWON-SI (KR)

(72) Inventors: Jisoo PARK, Suwon-si (KR); Jung Han LEE, Suwon-si (KR); Byung-Sung KIM, Suwon-si (KR); Jeonggu SIM, Suwon-si (KR); Kwanyoung CHUN, Suwon-si (KR)

(21) Appl. No.: 18/976,805

(22) Filed: Dec. 11, 2024

(30) Foreign Application Priority Data
Jun. 14, 2024 (KR) 10-2024-0077673

(51) Int. Cl. H10D 30/67; H10D 30/00; H10D 62/10; H10D 62/13

(52) U.S. Cl. CPC H10D 30/6729; H10D 30/501; H10D 30/6735; H10D 62/121; H10D 62/151

(57) ABSTRACT

A semiconductor device including a source/drain pattern disposed on a frontside of a substrate in a first region, a gate electrode adjacent to the source/drain pattern in a first direction and extending in a second direction, and a backside gate contact disposed in a field region, and connected to the gate electrode from a backside of the substrate, wherein the gate electrode includes a filling conductive film, and an electrode layer surrounding the filling conductive film, the filling conductive film includes an extension part extending in the second direction across the first and the second regions on the frontside of the substrate and a protruding part connected to the backside gate contact, the electrode layer disposed on the extension part, a sidewall of the protruding part is exposed by the electrode layer, and the field region has a field insulation layer surrounding the side wall of the protruding part.

### CROSS-REFERENCE TO RELATED APPLICATION(S)

This application claims priority under 35 U.S.C. § 119 to Korean Patent Application No. 10-2024-0077673, filed on Jun. 14, 2024, in the Korean Intellectual Property Office, the disclosure of which is herein incorporated by reference.

### BACKGROUND

### 1. Technical Field

Example embodiments relate to a semiconductor device.

### 2. Discussion of Related Art

Various scaling technologies are being researched to increase the density of semiconductor devices. For example, a multi-gate transistor have a multi-channel active pattern (or silicon body) in the shape of a fin or nanowire on a substrate and may include a gate on the surface of the multi-channel active pattern.

In some technologies, the source and drain of various semiconductor devices, such as logic circuits, may be connected to the metal wiring of the Back End Of Line (BEOL) through contact structures. The BEOL wiring include power lines disposed on the backside of the substrate, and a conductive through-structure may penetrate the substrate to connect to wiring on a frontside of the semiconductor devices.

### SUMMARY

An aspect of the present disclosure provides a semiconductor device with improved electrical reliability and with increased wiring pitch.

Another aspect also provides a downsized semiconductor device.

Another aspect also provides a semiconductor device which may have an improved process.

Aspects of the present disclosure are not limited to aspects described herein, and other aspects may be inferred from the following disclosure by those skilled in the art.

According to an aspect, there is provided a semiconductor device including an insulation substrate that includes a first activation region extending in a first direction, a second activation region extending in the first direction and spaced apart from the first activation region in a second direction intersecting the first direction, and a field region disposed between the first activation region and the second activation region, a field insulation layer disposed on the insulation substrate in the field region, a first source/drain pattern that is disposed on a frontside of the insulation substrate in the first activation region, a first gate electrode that is adjacent to the first source/drain pattern in the first direction and extending in the second direction, and a backside gate contact that is disposed in the field region, and connected to the first gate electrode by penetrating the insulation substrate from a backside of the insulation substrate, wherein the first gate electrode includes a first filling conductive film, and a first electrode layer surrounding at least a portion of the first filling conductive film, wherein the first filling conductive film includes an extension part that extends in the second direction across the first activation region, the second activation region and the field region on the frontside of the insulation substrate and a protruding part that is connected to the backside gate contact, and protruding from the extension part in a direction toward the insulation substrate, wherein the first electrode layer is disposed on at least a portion of the extension part, wherein a side wall of the protruding part is exposed by the first electrode layer, and wherein the field insulation layer surrounds the side wall of the protruding part.

According to another aspect, there is provided a semiconductor device that includes an insulation substrate that includes a first activation region extending in a first direction, a second activation region formed by extending in the first direction and being spaced apart from the first activation region in a second direction intersecting the first direction and a field region disposed between the first activation region and the second activation region, a first source/drain pattern that is disposed on a frontside of the insulation substrate in the first activation region, a first gate electrode that is adjacent to the first source/drain pattern in the first direction and extending in the second direction, a backside gate contact that is disposed in the field region, and connected to the first gate electrode by penetrating the insulation substrate from a backside of the insulation substrate, a second source/drain pattern that is disposed on the frontside of the insulation substrate in the second activation region, a first backside source/drain contact connecting a backside of the first source/drain pattern and a backside of the second source/drain pattern, and a first backside wiring line that is disposed on the backside of the insulation substrate in the field region, and connected to the backside gate contact and the first backside source/drain contact, wherein the first gate electrode has a backside that is disposed closer to the backside of the insulation substrate in the field region than in the first activation region and the second activation region.

According to another aspect, there is provided a semiconductor device that includes an insulation substrate that includes a plurality of sheet patterns extending in a first direction, and the insulation substrate includes a first activation region and a second activation region that are spaced apart from each other in a second direction intersecting with the first direction, and a field region disposed between the first activation region and the second activation region, a field insulation layer disposed on the insulation substrate in the field region, a first source/drain pattern that is disposed on a frontside of the insulation substrate, and connected to the plurality of sheet patterns in the first activation region, a first gate electrode that is spaced apart from the first source/drain pattern in the first direction and extending in the second direction, and a backside gate contact connected to the first gate electrode within the field insulation layer and penetrating the insulation substrate from a backside of the insulation substrate, a first backside source/drain contact that is connected to the first source/drain pattern by penetrating the insulation substrate from the backside of the insulation substrate, and extending in the second direction across the first activation region and the second activation region, and a first backside wiring line disposed in the field region and extending in the first direction on the backside of the insulation substrate, and connected to the backside gate contact and the first backside source/drain contact, wherein the first gate electrode includes a first filling conductive film, and a first electrode layer surrounding at least a portion of the first filling conductive film, the first filling conductive film includes an extension part that extends in the second direction across the first activation region, the second activation region, and the field region on the frontside of the insulation substrate and a protruding part that is connected to the backside gate contact in the field region, and protruding from the extension part toward the field insulation layer, wherein the protruding part penetrates the first electrode layer on the field insulation layer, wherein the first electrode layer surrounds at least a portion of the extension part, and the protruding part penetrates the first electrode layer in a third direction perpendicular to the first direction and the second direction, and wherein the field insulation layer surrounds a side wall of the protruding part.

Additional aspects of example embodiments will be set forth in part in the description which follows and, in part, will be apparent from the description, or may be learned by practice of the disclosure.

According to example embodiments, it is possible to improve the reliability of a semiconductor device.

According to example embodiments, it is possible to downsize a semiconductor device.

According to example embodiments, it is possible to relieve the difficulty of the process of manufacturing a semiconductor device.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a layout diagram for explaining a semiconductor device according to an example embodiment;

FIG. 2 is a cross-sectional view taken along line A-A of FIG. 1;

FIG. 3 is a cross-sectional view taken along line B-B of FIG. 1;

FIG. 4 is a cross-sectional view taken along line C-C of FIG. 1;

FIG. 5 is a cross-sectional view taken along line D-D of FIG. 1;

FIG. 6 is a cross-sectional view taken along line E-E of FIG. 1;

FIG. 7 is a diagram for explaining a semiconductor device according to an example embodiment;

FIG. 8 is a diagram for explaining a semiconductor device according to another example embodiment;

FIG. 9 is a diagram for explaining a semiconductor device according to another example embodiment;

FIG. 10 is an enlarged view illustrating a part P of FIG. 9;

FIG. 11 is a diagram for explaining a semiconductor device according to another example embodiment; and

FIGS. 12 to 38 are diagrams illustrating a method of manufacturing a semiconductor device according to some example embodiments.

### DETAILED DESCRIPTION

Hereinafter, embodiments of the present disclosure are described clearly and in detail such that those skilled in the art may easily reproduce the present disclosure. Inventive concepts may be implemented in various modifications and have various forms. It is to be understood, however, that the inventive concepts are not intended to be limited to the particular forms disclosed, but on the contrary, is intended to cover all modifications, equivalents, and alternatives falling within the spirit and scope of the inventive concepts.

Terms or words used in the specification and claims should not be construed as limited to their common or dictionary meanings. Further, the terms or words should be interpreted with meaning and concept consistent with the technical idea of the present disclosure based on the principle that the inventor may appropriately define the concept of terms in order to explain the invention in the best way. Example embodiments described in this specification and the configurations shown in the drawings do not necessarily represent the entire technical idea of the present disclosure.

In the following description, singular expressions include plural expressions unless the context clearly dictates otherwise. It will be understood that, when an element (for example, a first element) is “(operatively or communicatively) coupled with/to” or “connected to” another element (for example, a second element), the element may be directly coupled with/to another element, and there may be an intervening element (for example, a third element) between the element and another element. The terms “have,” “may have,” “include,” and “may include” as used herein indicate the presence of corresponding features (for example, elements such as numerical values, functions, operations, or parts), and do not preclude the presence of additional features.

Further, in the following description, directional expressions such as an upper side, top, a lower side, bottom, a side, front and a back side may be expressed based on the direction shown in the drawing. If the direction of the object changes, directional expressions may be expressed differently. The shapes and sizes of elements in the drawings may be exaggerated for clearer explanation.

Here, a first direction D1 may intersect with a second direction D2. The first direction D1 and the second direction D2 may be perpendicular to each other. The first direction D1 and the second direction D2 may form a plane. The first direction D1 and the second direction D2 may form a horizontal plane. A third direction D3 may intersect the first direction D1 and the second direction D2. The third direction D3 may be the thickness direction of the insulation substrate 100. For example, the third direction D3 may be perpendicular to the first direction D1 and the second direction D2.

Some drawings of a semiconductor device according to some example embodiments illustrate a Fin-type transistor (FinFET) including a channel region in the shape of a fin-type pattern, transistor including nanowires or nanosheets, and a multi-bridge channel field effect transistor (MBCFET), but the present disclosure is not limited thereto.

In some example embodiments, the semiconductor device may include a tunneling transistor (tunneling FET), vertical transistor (Vertical FET), or a three-dimensional (3D) transistor. In some example embodiments, the semiconductor device may include planar transistors. In addition, the technical idea of the present disclosure can be applied to 2D material-based transistors (2D material based FETs) and their heterostructure. Further, a semiconductor device according to some example embodiments may include a bipolar junction transistor or a horizontal double diffusion transistor (LDMOS).

Hereinafter, example embodiments according to the technical idea of the present invention will be described with reference to the attached drawings.

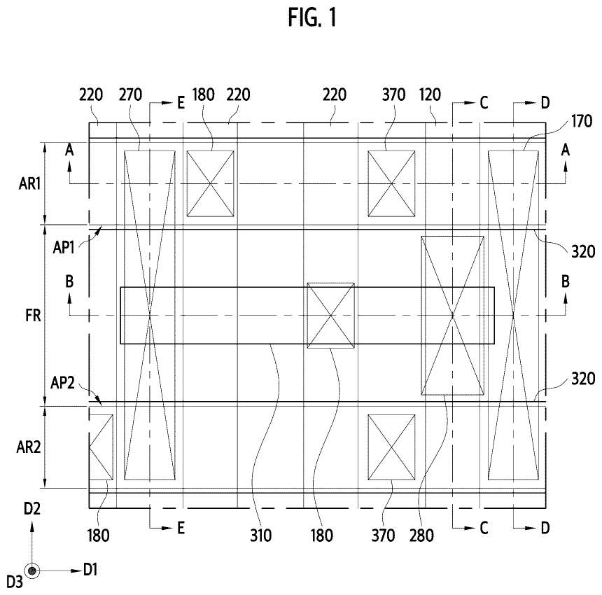

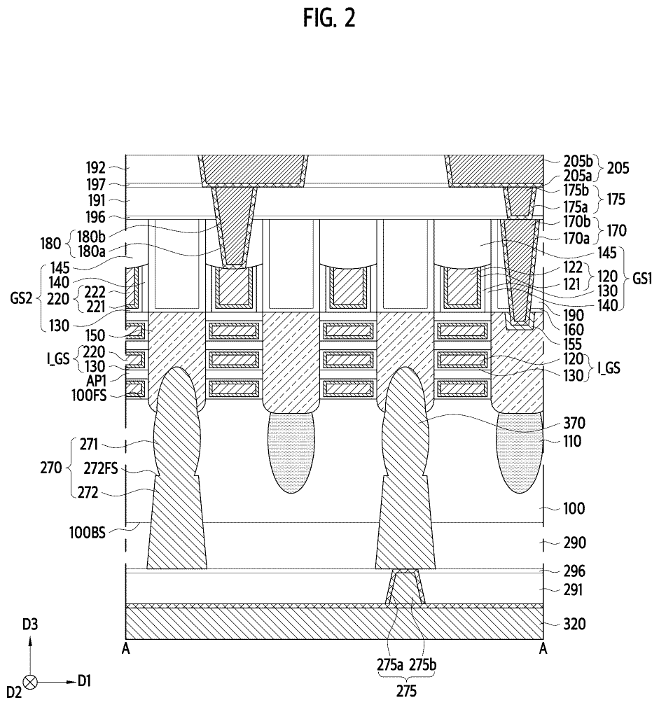

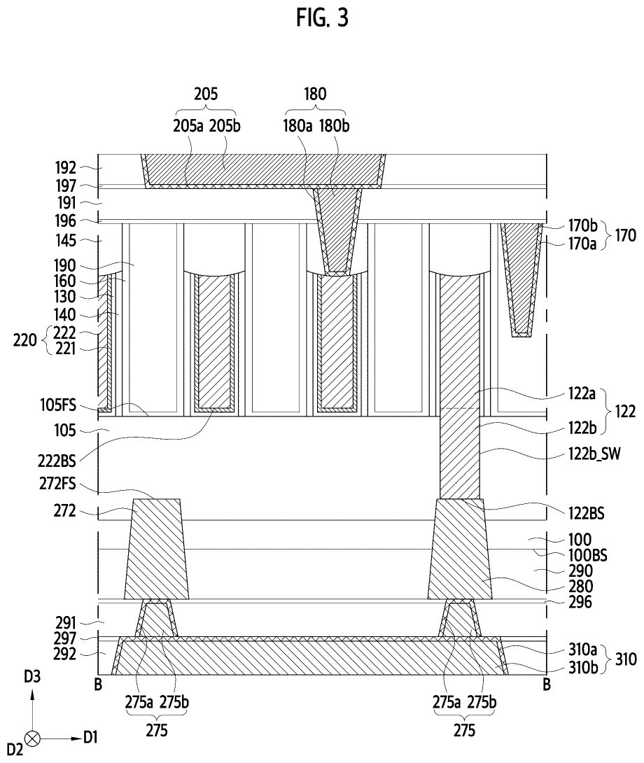

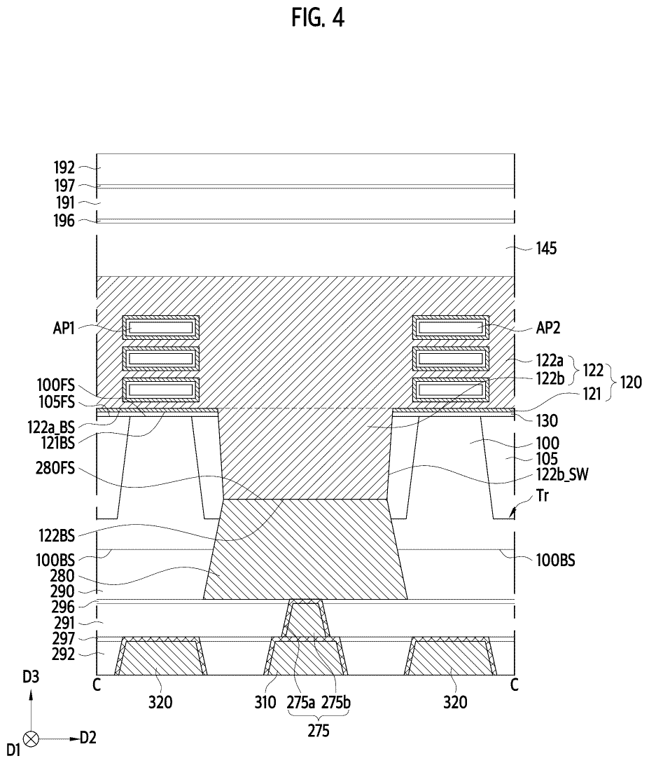

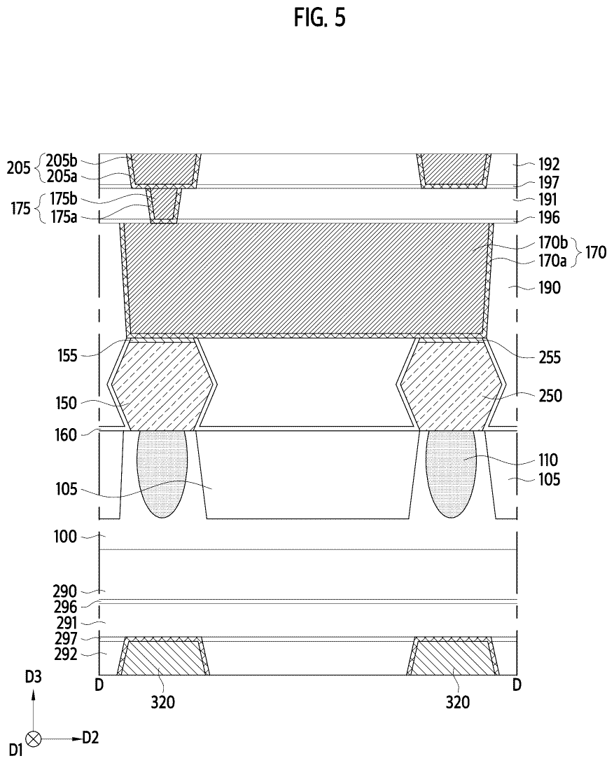

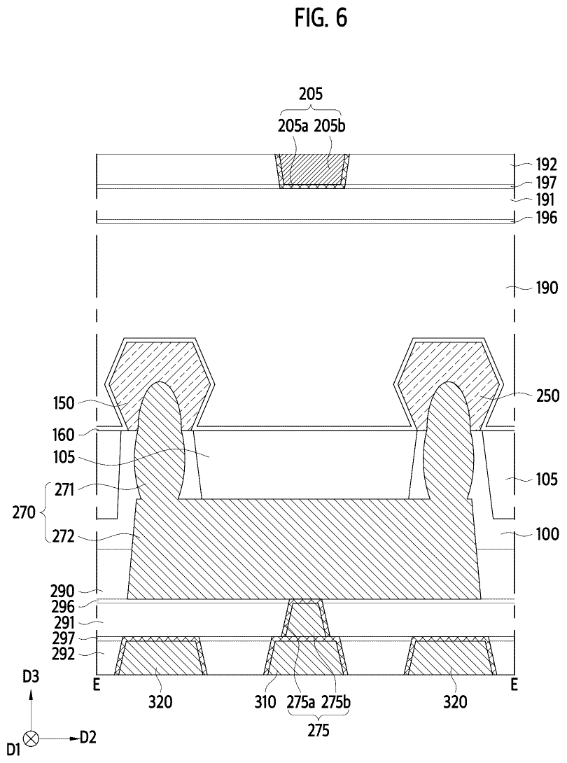

FIG. 1 is a layout diagram for explaining a semiconductor device according to an example embodiment. FIG. 2 is a cross-sectional view taken along line A-A of FIG. 1. FIG. 3 is a cross-sectional view taken along line B-B of FIG. 1. FIG. 4 is a cross-sectional view taken along line C-C of FIG. 1. FIG. 5 is a cross-sectional view taken along line D-D of FIG. 1. FIG. 6 is a cross-sectional view taken along line E-E of FIG. 1.

In order to facilitate understanding of the present disclosure, a frontside wiring line 205, a frontside wiring via 175, and a backside wiring via 275 are omitted from the layout diagram of FIG. 1.

Referring to FIGS. 1 to 6, the semiconductor device may include an insulation substrate 100, a first gate electrode 120, a second gate electrode 220, a first source/drain pattern 150, a second source/drain pattern 250, a frontside source/drain contact 170, a first backside source/drain contact 270, a second backside source/drain contact 370, a frontside gate contact 180, a backside gate contact 280, the frontside wiring line 205, a first backside wiring line 310 and a second backside wiring line 320.

According to some example embodiments, the insulation substrate 100 may include a first activation region AR1, a second activation region AR2, and a field region FR.

According to some example embodiments, each of the first activation region AR1 and the second activation region AR2 may extend in the first direction D1. The first activation region AR1 and the second activation region AR2 may be spaced apart from each other in the second direction D2. The first activation region AR1 and the second activation region AR2 may be separated by the field region FR. The first activation region AR1 and the second activation region AR2 may be separated in the second direction D2 by the field region FR.

According to some example embodiments, the field region FR may be disposed between the first activation region AR1 and the second activation region AR2. The field region FR may border the first activation region AR1 and the second activation region AR2. The field region FR may have a shallow trench isolation (STI) structure. However, example embodiments are not limited thereto. For example, the field region FR may be defined by a deep trench.

In other words, an isolation layer may be disposed around the first activation region AR1 and the second activation region AR2, which may be spaced apart from each other. Here, in the insolation layer, a part between the first activation region AR1 and the second activation region AR2 may be the field region FR. For example, the part where the channel region of a transistor, which is an example of a semiconductor device, is formed may be an activation region, and the part that separates the channel region of the transistor formed in the activation region may be a field region. Alternatively, an activation region may be a part where a nano sheet or a fin-type pattern is formed, which may be a channel region of a transistor, and a field region may be a region where a fin-type pattern or a nano sheet is not formed, which may be a channel region.

As illustrated in FIG. 4, the field region FR may be defined by a trench Tr, but is not limited thereto. Further, a person skilled in the art to which the present disclosure pertains may distinguish which part is the field region and which part is the activation region.

In an example embodiment, between the first activation region AR1 and the second activation region AR2, one may be a PMOS formation region and the other may be an NMOS formation region. In another example embodiment, the first activation region AR1 and the second activation region AR2 may be PMOS formation regions. In another example embodiment, the first activation region AR1 and the second activation region AR2 may be NMOS formation regions.

According to some example embodiments, the insulation substrate 100 may be disposed on a first backside interlayer insulating film 290. The insulation substrate 100 may be disposed at a bottom of a first active pattern AP1 and a second active pattern AP2. For example, the insulation substrate 100 may be disposed between the first backside interlayer insulating film 290 and the first active pattern AP1. The insulation substrate 100 may be disposed between the first backside interlayer insulating film 290 and the second active pattern AP2. For example, the insulation substrate 100 may include at least one of silicon oxide, silicon nitride, silicon oxynitride or a low-k dielectric material.

According to some example embodiments, a supporter 110 may be disposed in the insulation substrate 100. The supporter 110 may be surrounded by the insulation substrate 100. The supporter 110 may be disposed at the bottom of the first source/drain pattern 150 and the second source/drain pattern 250. For example, the supporter 110 may be disposed at the bottom of the first source/drain pattern 150 and the second source/drain pattern 250 where the first backside source/drain contact 270 and the second backside source/drain contact 370 are not connected. For example, the supporter 110 and the first backside source/drain contact 270 may be alternately disposed at the bottom of the first source/drain pattern 150 as illustrated in FIG. 2. The supporter 110 may include, for example, silicon germanium.

According to some example embodiments, the first activation region AR1 may include the first active pattern AP1. The second activation region AR2 may include the second active pattern AP2. Each of the first active pattern AP1 and the second active pattern AP2 may extend in the first direction D1. The first active pattern AP1 and the second active pattern AP2 may be multi-channel active patterns. For example, each of the first active pattern AP1 and the second active pattern AP2 may include multiple sheet patterns. According to some example embodiments, in the semiconductor device, the first active pattern AP1 and the second active pattern AP2 may be active patterns containing nano sheets or nanowires.

According to some example embodiments, the first active pattern AP1 and the second active pattern AP2 may be disposed on the insulation substrate 100. The first active pattern AP1 and the second active pattern AP2 may be spaced apart from the insulation substrate 100 in the third direction D3. The first active pattern AP1 and the second active pattern AP2 may be disposed on a frontside of the insulation substrate 100FS.

According to some example embodiments, each of the first active pattern AP1 and the second active pattern AP2 may include an upper side and a lower side disposed opposite to each other in the third direction D3. Each lower side of the first active pattern AP1 and the second active pattern AP2 may face the insulation substrate 100. It is illustrated that each of the first active pattern AP1 and the second active pattern AP2 may include three sheet patterns arranged in the third direction D3, but the illustration is only for convenience of explanation and the present disclosure is not limited thereto. For example, each of the first active pattern AP1 and the second active pattern AP2 may include two or more sheet patterns arranged in the third direction D3.

In an example embodiment, the sheets of the active pattern may be disposed in a stacked structure. Sheets of the stacked structure may be disposed apart from each other in the third direction D3. In an example embodiment, a sheet pattern may have a width that is greater than a height, however the present disclosure is not limited thereto. For example, the sheet pattern may be implemented as a wire, which may have a width equal to a height.

In an example embodiment, the width of sheet pattern of the first active pattern AP1 in the second direction D2 may be equal to, larger than, or smaller than the width in the second direction D2 of an upper portion of the insulation substrate 100 disposed at the bottom of the first active pattern AP1. For example, the upper portion of the insulation substrate 100 disposed at the bottom of the first active pattern AP1 may be a vertical portion disposed above a horizontal portion of the substrate 100. It is illustrated that width of the multiple sheet patterns of the first active pattern AP1 in the second direction D2 may be the same, but the present disclosure is not limited thereto.

According to some example embodiments, the first active pattern AP1 and the second active pattern AP2 may include, for example, silicon or germanium, which may be considered elemental semiconductor materials. Further, the first active pattern AP1 and the second active pattern AP2 may include a compound semiconductor. For example, a group IV-IV compound semiconductor or a group III-V compound semiconductor may be included.

For example, a IV-IV group compound semiconductor may be a binary compound or a ternary compound comprising at least two of carbon (C), silicon (Si), germanium (Ge), or tin (Sn), or may be compounds doped with group IV elements.

For example, a III-V group compound semiconductor may be a binary compound, a ternary compound, or a quaternary compound formed by combining at least one of the group III elements aluminum (Al), gallium (Ga), or indium (In) with a group V element such as phosphorus (P), arsenic (As), or antimony (Sb).

According to some example embodiments, the first active pattern AP1 and the second active pattern AP2 may be substantially the same, and hereinafter, example embodiments may be described in the context of the first active pattern AP1. These description may also apply to the second active pattern AP2.

According to some example embodiments, a field insulation layer 105 may be disposed in the field region FR. The field insulation layer 105 may be disposed on the insulation substrate 100. For example, the field insulation layer 105 may be disposed between a portion of the insulation substrate 100 that overlaps the first active pattern AP1 in the third direction D3 and a portion of the insulation substrate 100 that overlaps the second active pattern AP2 in the third direction D3. The field insulation layer 105 may fill at least a portion of the trench Tr formed on the insulation substrate 100.

According to some example embodiments, the field insulation layer 105 may cover a side wall of the insulation substrate 100. A frontside of the field insulation layer 105FS may be disposed on a same plane as the frontside of the insulation substrate 100FS. In another example embodiment, the field insulation layer 105 may cover a portion of the side wall of the insulation substrate 100. In this case, the portion of the insulation substrate 100 may protrude in the third direction D3 above the frontside of the field insulation layer 105FS. In an example embodiment, the field insulation layer 105 may include an oxide film, a nitride film, or an oxynitride film, or a combination thereof. It is illustrated that the field insulation layer 105 is a single layer, but this is only for convenience of explanation and the present disclosure is not limited thereto. For example, the field insulation layer 105 may be formed of multiple layers.

According to some example embodiments, a first gate structure GS1 and a second gate structure GS2 may be disposed on the frontside of the insulation substrate 100FS. Each of the first gate structure GS1 and the second gate structure GS2 may extend in the second direction D2. The first gate structure GS1 and the second gate structure GS2 may be spaced apart in the first direction D1. The first gate structure GS1 and the second gate structure GS2 may be adjacent to each other in the first direction D1.

According to some example embodiments, the first gate structure GS1 and the second gate structure GS2 may be disposed on the first active pattern AP1 and the second active pattern AP2. For example, the first gate structure GS1 and the second gate structure GS2 may intersect with the first active pattern AP1 and the second active pattern AP2.

According to some example embodiments, each of the first gate structure GS1 and the second gate structure GS2 may wrap the first active pattern AP1. Each of the first gate structure GS1 and the second gate structure GS2 may wrap the second active pattern AP2. Specifically, each of the first gate electrode 120 and the second gate electrode 220 may wrap multiple sheet patterns included in the first active pattern AP1 and multiple sheet patterns included in the second active pattern AP2.

According to some example embodiments, the first gate structure GS1 and the second gate structure GS2 may include at least one of the first gate electrode 120 or the second gate electrode 220, a gate insulating film 130, a gate spacer 140 and a gate capping film 145. For example, the first gate structure GS1 may include the first gate electrode 120, the gate insulating film 130, the gate spacer 140 and the gate capping film 145. The second gate structure GS2 may include the second gate electrode 220, the gate insulating film 130, the gate spacer 140 and the gate capping film 145.

FIG. 1 illustrates that the first gate electrode 120 of the first gate structure GS1 and the second gate electrode 220 of the second gate structure GS2 may be disposed across the first activation region AR1 and the second activation region AR2. However, the present disclosure is not limited thereto. In an example embodiment, the first gate structure GS1 and the second gate structure GS2 may not extend continuously in the second direction D2 across the first activation region AR1 and the second activation region AR2, and may be separated at the field region FR. In this case, the first gate structure GS1 and the second gate structure GS2 that extend in the second direction D2 but intersect with the first activation region AR1 and the first gate structure GS1 and the second gate structure GS2 that extend in the second direction D2 but intersect with the second activation region AR2 may be spaced apart from each other, in the second direction D2.

According to some example embodiments, the first gate structure GS1 and the second gate structure GS2 may include a plurality of inner gate structures I_GS. Referring to FIG. 2 and FIG. 4, the plurality of inner gate structures I_GS may be disposed in the stacked structure of the first active patterns AP1 in the third direction D3, and between the insulation substrate 100 and the first active pattern AP1. The plurality of inner gate structures I_GS may be disposed between the first active patterns AP1. The inner gate structures I_GS may be disposed between the frontside of the insulation substrate 100FS and the lower side of the first active pattern AP1, and between the upper side of the first active pattern AP1 and the lower side of the first active pattern AP1 facing each other in the third direction D3.

According to some example embodiments, the number of inner gate structures I_GS may be the same as the number of the first active patterns AP1. The inner gate structures I_GS contact the frontside of the insulation substrate 100FS, the upper side of the first active pattern AP1, and the lower side of the first active pattern AP1. The inner gate structures I_GS may contact the first source/drain pattern 150 or the second source/drain pattern 250, which are described herein.

According to some example embodiments, the inner gate structure I_GS may include the gate insulating film 130 and one of the first gate electrode 120 or the second gate electrode 220 disposed between the first active patterns AP1 disposed in the stacked structure in the third direction D3 and between the insulation substrate 100 and the first active pattern AP1. The inner gate structure I_GS may be disposed between the second activation patters AP2 disposed in the stacked structure in the third direction D3, and between the insulation substrate 100 and the second active pattern AP2.

According to some example embodiments, the first gate electrode 120 and the second gate electrode 220 may extend in the second direction D2. The first gate electrode 120 and the second gate electrode 220 may extend in the second direction D2 between the first source/drain patterns 150 and between the second source/drain patterns 250. The first gate electrode 120 and the second gate electrode 220 may be spaced apart from each other in the first direction D1.

According to some example embodiments, the first gate electrode 120 may be connected to the backside gate contact 280. For example, in the field region FR, the first gate electrode 120 may overlap the backside gate contact 280 in the third direction D3.

According to some example embodiments, the second gate electrode 220 may be connected to the frontside gate contact 180. For example, in the first activation region AR1, the second activation region AR2 or the field region FR, the second gate electrode 220 may overlap the frontside gate contact 180 in the third direction D3.

According to some example embodiments, the first gate electrode 120 may intersect the insulation substrate 100 and the field insulation layer 105. The first gate electrode 120 may cover the first active pattern AP1 and the second active pattern AP2.

According to some example embodiments, in the first activation region AR1 and the second activation region AR2, the first gate electrode 120 may be disposed on the frontside of the insulation substrate 100FS. In the first activation region AR1 and the second activation region AR2, the first gate electrode 120 may not overlap the field insulation layer 105 in the first direction D1 or the second direction D2.

According to some example embodiments, in the field region FR, at least a portion of the first gate electrode 120 may be disposed in the field insulation layer 105. In the field region FR, at least a portion of the first gate electrode 120 may overlap the field insulation layer 105 in the first direction D1 or the second direction D2.

According to some example embodiments, the first gate electrode 120 may include a first electrode layer 121 and a first filling conductive film 122.

According to some example embodiments, the first electrode layer may include a material that adjusts the threshold voltage of the transistor. The first electrode layer 121 may be implemented as a first work function adjustment film. The first electrode layer 121 may be disposed on the gate insulating film 130. The first electrode layer 121 may extend along the profile of the gate insulating film 130. The first electrode layer 121 may surround at least a portion of the first filling conductive film 122.

According to some example embodiments, the first electrode layer 121 may include a metal-containing material with a P-type work function or a metal-containing material with an N-type work function. The first electrode layer 121 may be made of a single layer or multiple layers. For example, the first electrode layer 121 may include a conductive film that may adjust the work function of the first filling conductive film 122. According to an embodiment, the work function of the first filling conductive film 122 depending on a thickness of the first electrode layer 121. For example, the first electrode layer 121 may be a work function adjustment film that includes at least one of titanium nitride (TiN), tantalum nitride (TaN), titanium carbide (TiC), tantalum carbide (TaC), titanium aluminum carbide (TiAlC), or titanium oxynitride (TION), or combinations thereof.

According to some example embodiments, the first filling conductive film 122 may be disposed on the first electrode layer 121. The first filling conductive film 122 may fill the space formed by the first electrode layer 121 between the gate spacers 140. For example, the first filling conductive film 122 may include at least one of tungsten (W), or aluminum (Al) or combinations thereof. However, example embodiments are not limited thereto. The first filling conductive film 122 may be made of a single layer or multiple layers.

According to some example embodiments, the first filling conductive film 122 may include an extension part 122a and a protruding part 122b. The extension part 122a may extend in the second direction D2 across the first activation region AR1, the second activation region AR2 and the field region FR. The protruding part 122b may be disposed in the field region FR. The protruding part 122b may protrude from the extension part 122a in the field region FR in a direction toward a backside of the insulation substrate 100BS. The protruding part 122b may penetrate the first electrode layer 121 on the field insulation layer 105. For example, the first electrode layer 121 may expose a side wall of the protruding part 122b and the protruding part 122b may penetrate the first electrode layer 121 in the third direction D3 toward the insulation substrate 100.

According to some example embodiments, in the first activation region AR1 and the second activation region AR2, the first electrode layer 121 and the first filling conductive film 122 may overlap in the third direction D3. In other words, in the first activation region AR1 and the second activation region AR2, the extension part 122a may overlap the first electrode layer 121 in the third direction D3. For example, in the first activation region AR1 and the second activation region AR2, a bottom surface of the extension part 122a_BS may be covered by the first electrode layer 121.

According to some example embodiments, in the first activation region AR1 and the second activation region AR2, a backside of the first filling conductive film 122 may be the bottom surface of the extension part 122a_BS. Therefore, in the first activation region AR1 and the second activation region AR2, the first electrode layer 121 may overlap the backside of the first filling conductive film 122 in the third direction D3. Specifically, in the first activation region AR1 and the second activation region AR2, the first electrode layer 121 may cover the bottom surface of the extension part 122a_BS, and thus the backside of the first electrode layer 121 and the first filling conductive film 122 may overlap in the third direction D3 in the first activation region AR1 and the second activation region AR2.

According to some example embodiments, in the field region FR, the extension part 122a may be connected to the protruding part 122b. In the field region FR, the extension part 122a and the protruding part 122b may overlap in the third direction D3. A part of extension part 122a connected to the protruding part 122b may not overlap the first electrode layer 121 in the third direction D3. In other words, in the field region FR, the first electrode layer 121 and the first filling conductive film 122 may not overlap in the third direction D3.

According to some example embodiments, in the field region FR, the backside of the first filling conductive film 122 may be a bottom surface of the first filling conductive film 122BS, which may be the bottom surface of the protruding part 122b. Therefore, in the field region FR, the first electrode layer 121 may not overlap the backside of the first filling conductive film 122 in the third direction D3. Specifically, in the field region FR, the first electrode layer 121 does not cover the bottom surface of the first filling conductive film 122BS, and thus the backsides of the first electrode layer 121 and the first filling conductive film 122 may not overlap in the third direction D3 in the field region FR.

According to some example embodiments, the protruding part 122b may overlap the backside gate contact 280 in the third direction D3. The protruding part 122b may be disposed between the extension part 122a and the backside gate contact 280. The protruding part 122b may electrically connect the extension part 122a and the backside gate contact 280. The bottom surface of the first filling conductive film 122BS, which may be the bottom surface of the protruding part 122b, may contact the frontside of the backside gate contact 280FS.

According to some example embodiments, in the third direction D3, the protruding part 122b may protrude from the extension part 122a toward the backside of the insulation substrate 100BS. The backside gate contact 280 may extend to the protruding part 122b. Therefore, when the protruding part 122b protrudes from the extension part 122a toward the backside of the insulation substrate 100BS, the aspect ratio of the backside gate contact 280 may be reduced, and the first gate electrode 120 and the backside gate contact 280 may be stably connected.

According to some example embodiments, relative to the backside of the insulation substrate 100BS, the bottom surface of the protruding part 122b may be disposed at a same level as a frontside of the via connecting part 272FS. In other words, the bottom surface of the first filling conductive film 122BS, which may be the bottom surface of the protruding part 122b, may be coplanar with the frontside of the via connecting part 272FS. Relative to the frontside of the field insulation layer 105FS, the bottom surface of the first filling conductive film 122BS and the frontside of the via connecting part 272FS may have the same depth.

According to some example embodiments, in the second direction D2, the width of the bottom surface of the protruding part 122b and the frontside of the backside gate contact 280FS may be the same. For example, in the second direction D2, the width of the bottom surface of the first filling conductive film 122BS, which may be the bottom surface of the protruding part 122b, and the width of the frontside of the backside gate contact 280FS may be the same.

According to some example embodiments, in the field region FR, the first electrode layer 121 may not cover the bottom surface of the first filling conductive film 122BS. In the field region FR, the bottom surface of the first filling conductive film 122BS may be the bottom surface of the protruding part 122b.

According to some example embodiments, the first electrode layer 121 may overlap the extension part 122a in the first direction D1 in the first activation region AR1 and the second activation region AR2. Specifically, in the first activation region AR1 and the second activation region AR2, the first electrode layer 121 may cover a side wall of the extension part 122a. For example, in the first activation region AR1 and the second activation region AR2, the first electrode layer 121 may be disposed between the extension part 122a and the gate insulating film 130.

According to some example embodiments, in the field region FR, the first electrode layer 121 may not be placed on a side wall 122b_SW of the protruding part. For example, in the field region FR, the protruding part 122b may be in direct contact with the field insulation layer 105. The side wall 122b_SW of the protruding part may contact the field insulation layer 105 in the first direction D1 and the second direction D2. In other words, both the side wall 122b_SW of the protruding part shown on the cross section cut along the first direction D1 and the side wall 122b_SW of the protruding part shown on the cross section cut along the second direction D2 may contact the field insulation layer 105. The field insulation layer 105 may surround the side wall 122b_SW of the protruding part. The first electrode layer 121 may not overlap the field insulation layer 105 in the first direction D1 or the second direction D2.

According to some example embodiments, in the field region FR, the first electrode layer 121 may expose at least a portion of the side wall of the extension part 122a. In the field region FR, the first electrode layer 121 may expose the side wall of the portion of the extension part 122a that overlaps the protruding part 122b and the third direction D3. The first electrode layer 121 may expose the extension part 122a in the first direction D1 in the field region FR. For example, in the field region FR, the side wall of the extension part 122a may be in direct contact with the gate insulating film 130. Here, in the first direction D1 in the field region FR, the width of the extension part 122a and the width of the protruding part 122b may be the same. In other words, the side wall of the extension part 122a and the side wall 122b_SW of the protruding part may be on the same plane.

According to some example embodiments, the backside of the first gate electrode 120 may include a bottom surface of the first work function adjustment film 121BS and the bottom surface of the first filling conductive film 122BS. Specifically, in the first activation region AR1 and the second activation region AR2, the backside of the first gate electrode 120 may be the bottom surface of the first work function adjustment film 121BS. In the field region FR, the backside of the first gate electrode 120 may be the bottom surface of the first filling conductive film 122BS.

According to some example embodiments, the backside of the first gate electrode 120 may be disposed closer to the backside of the insulation substrate 100BS in the field region FR than the first activation region AR1 and the second activation region AR2. The bottom surface of the first filling conductive film 122BS may be the bottom surface of the protruding part 122b, and the backside of the first gate electrode 120 may be adjacent to the backside of the insulation substrate 100BS in the field region FR. The protruding part 122b may be omitted from the backside of the first gate electrode 120 in the first activation region AR1 and the second activation region AR2.

According to some example embodiments, the second gate electrode 220 may be substantially the same as the first gate electrode 120. A description of certain differences between the first gate electrode 120 and the second gate electrode 220 follows.

According to some example embodiments, the second gate electrode 220 may be disposed on the frontside of the insulation substrate 100FS. In the first activation region AR1, the second activation region AR2 and the field region FR, the second gate electrode 220 may be disposed on the frontside of the insulation substrate 100FS. In the field region FR, the second gate electrode 220 may not overlap the field insulation layer 105 in the first direction D1 or the second direction D2.

According to some example embodiments, the second gate electrode 220 may include a second electrode layer 221 and a second filling conductive film 222.

According to some example embodiments, the second electrode layer 221 may include a material that adjusts the threshold voltage of the transistor. The second electrode layer 221 may be implemented as a second work function adjustment film. In the first activation region AR1, the second activation region AR2 and the field region FR, the second electrode layer 221 and the second filling conductive film 222 may overlap in the third direction D3. For example, in the first activation region AR1, the second activation region AR2 and the field region FR, the second electrode layer 221 may cover a bottom surface of the second filling conductive film 222BS.

Specifically, the second electrode layer 221 may cover the bottom surface of the second filling conductive film 222BS in the field region FR. This may be due to the protruding part 122b of the first filling conductive film 122 protruding from the extension part 122a toward the field insulation layer 105 in the field region FR.

According to some example embodiments, relative to the backside of the insulation substrate 100BS, the bottom surface of the second filling conductive film 222BS may be disposed above the bottom surface of the first filling conductive film 122BS. In other words, in the third direction D3, the bottom surface of the first filling conductive film 122BS may be disposed closer to the backside of the insulation substrate 100BS than to the bottom surface of the second filling conductive film 222BS. This may be due to the bottom surface of the protruding part 122b of the first filling conductive film 122 forming the bottom surface of the first filling conductive film 122BS.

The cross-sectional views such as FIG. 2 and FIG. 3 illustrate that upper sides of the first gate electrode 120 and the second gate electrode 220 are concave curved surfaces, but the present disclosure is not limited thereto. The upper sides of the first gate electrode 120 and the second gate electrode 220 may be flat.

According to some example embodiments, the first gate electrode 120 and the second gate electrode 220 may include at least one of metals, metal alloys, conductive metal nitrides, metal silicides, doped semiconductor materials, conductive metal oxides or conductive metal oxynitrides. Each of the first gate electrode 120 and the second gate electrode 220 may include at least one of, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TIC), tantalum carbonitride (TaCN), tungsten (W), aluminum (Al), copper (Cu), cobalt (Co), titanium (Ti), tantalum (Ta), nickel (Ni), platinum (Pt), nickel platinum (NiPt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), or vanadium (V), or combinations thereof. However, the present disclosure is not limited thereto. The conductive metal oxides and the conductive metal oxynitrides may include oxidized forms of materials described herein, but the present disclosure is not limited thereto. For example, each of the first filling conductive film 122 of the first gate electrode 120 and the second filling conductive film 222 of the second gate electrode 220 may contain at least one of the substances described herein.

According to some example embodiments, the gate insulating film 130 may extend along the frontside of the insulation substrate 100FS and the frontside of the field insulation layer 105FS. The gate insulating film 130 may cover multiple first active patterns AP1. The gate insulating film 130 may cover multiple second active patterns AP2. The gate insulating film 130 may be disposed along the perimeter of the first active pattern AP1 and the perimeter of the second active pattern AP2. The first gate electrode 120 and the second gate electrode 220 may be disposed on the gate insulating film 130.

According to some example embodiments, the gate insulating film 130 may directly contact the frontside of the insulation substrate 100FS. The gate insulating film 130 may directly contact the frontside of the field insulation layer 105FS.

According to some example embodiments, the gate insulating film 130 may be disposed between the first gate electrode 120 and the first active pattern AP1, may be disposed between the second gate electrode 220 and the first active pattern AP1, may be disposed between the first gate electrode 120 and the second active pattern AP2, and may be disposed between the second gate electrode 220 and the second active pattern AP2. According to some example embodiments, in the semiconductor device, the gate insulating film 130 included in the inner gate structures I_GS may contact the first source/drain pattern 150 and the second source/drain pattern 250, which is explained herein.

According to some example embodiments, the gate insulating film 130 may include silicon oxide, silicon oxynitride, silicon nitride, or a high dielectric constant material with a higher dielectric constant than the silicon oxide. The high dielectric constant material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

According to some example embodiments, it is illustrated that the gate insulating film 130 is a single film, but it is merely for convenience of explanation and the present disclosure is not limited thereto. The gate insulating film 130 may include multiple films. The gate insulating film 130 may include a high dielectric constant insulating film and an interfacial layer disposed between the first active pattern AP1 and one of the first gate electrode 120 and the second gate electrode 220, and between the second active pattern AP2 and a one of the first gate electrode 120 and the second gate electrode 220. For example, the interfacial layer may not be formed according to the profile of the frontside of the field insulation layer 105FS.

According to some example embodiments, the semiconductor device may include a negative capacitance (NC) FET using a negative capacitor. For example, the gate insulating film 130 may include a ferroelectric material layer with ferroelectric properties and a paraelectric material layer with paraelectric properties.

According to some example embodiments, the ferroelectric material layer may have negative capacitance, and the paraelectric material layer may have positive capacitance. For example, when two or more capacitors are connected in series and the capacitance of each capacitor has a positive value, the overall capacitance is reduced compared to the capacitance of each individual capacitor. On the other hand, when at least one of the capacitances of two or more capacitors connected in series has a negative value, the overall capacitance may be positive and greater than the absolute value of each individual capacitance.

When a ferroelectric material layer with negative capacitance and a paraelectric material layer with positive capacitance are connected in series, the overall capacitance value of the ferroelectric material layer and the paraelectric material layer connected in series may be increased. By taking advantage of the overall capacitance value increasing, a transistor containing a ferroelectric material layer may have a subthreshold swing (SS) of less than 60 mV/decade at room temperature.

According to some example embodiments, the ferroelectric material layer may have ferroelectric properties. For example, the ferroelectric material layer may include at least one of hafnium oxide, hafnium zirconium oxide, barium strontium titanium oxide, barium titanium oxide, or lead zirconium titanium oxide. Here, in an example embodiment, hafnium zirconium oxide may be a material in which zirconium (Zr) is doped into hafnium oxide. In another example embodiment, hafnium zirconium oxide may be a compound of hafnium (Hf), zirconium (Zr) and oxygen (O).

According to some example embodiments, the ferroelectric material layer may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). Depending on what ferroelectric material the ferroelectric material layer contains, the type of dopant included in the ferroelectric material layer may vary.

According to some example embodiments, when the ferroelectric material layer contains hafnium oxide, the dopant included in the ferroelectric material layer may include, for example, at least one of gadolinium (Gd), silicon (Si), zirconium (Zr), aluminum (Al) or yttrium (Y).

According to some example embodiments, when the dopant is aluminum (Al), the ferroelectric material layer may contain 3 to 8 at % (atomic %) of aluminum. Here, the ratio of dopant may be the ratio of aluminum to the sum of hafnium and aluminum.

According to some example embodiments, when the dopant is silicon (Si), the ferroelectric material layer may contain 2 to 10 at % of silicon. When the dopant is yttrium (Y), the ferroelectric material layer may contain 2 to 10 at % yttrium. When the dopant is gadolinium (Gd), the ferroelectric material layer may contain 1 to 7 at % of gadolinium. When the dopant is zirconium (Zr), the ferroelectric material layer may contain 50 to 80 at % zirconium.

According to some example embodiments, the paraelectric material layer may have paraelectric properties. For example, the paraelectric material layer may include at least one of silicon oxide or a metal oxide having a high dielectric constant. For example, the metal oxide included in the paraelectric material layer may include at least one of hafnium oxide, zirconium oxide or aluminum oxide. However, the present disclosure is not limited thereto.

According to some example embodiments, the ferroelectric material layer and the paraelectric material layer may include the same material. The ferroelectric material layer may have ferroelectric properties, and the paraelectric material layer may not have ferroelectric properties. For example, when the ferroelectric material layer and the paraelectric material layer contain hafnium oxide, the crystal structure of hafnium oxide contained in the ferroelectric material layer is different from the crystal structure of hafnium oxide contained in the paraelectric material layer.

According to some example embodiments, the ferroelectric material layer may have a thickness that has ferroelectric properties. For example, the thickness of the ferroelectric material layer may be 0.5 to 10 nm. However, the present disclosure is not limited thereto. The threshold thickness representing ferroelectric properties may vary for each ferroelectric material, and thus the thickness of the ferroelectric material layer may vary depending on the ferroelectric material.

In an example embodiment, the gate insulating film 130 may include one ferroelectric material layer. In another example embodiment, the gate insulating film 130 may include a plurality of ferroelectric material layers spaced apart from each other. The gate insulating film 130 may have a laminated film structure in which a plurality of ferroelectric material layers and a plurality of paraelectric material layers are alternately stacked.

According to some example embodiments, the gate spacer 140 may be disposed on side walls of the first gate electrode 120 and the second gate electrode 220. The gate spacer 140 may be omitted from between the insulation substrate 100 and the first active pattern AP1, and may be omitted from between the first active patterns AP1 that are adjacent in the third direction D3.

According to some example embodiments, for example, the gate spacer 140 may include at least one of silicon nitride (SiN), silicon oxynitride (SiON), silicon oxide (SiO₂), silicon oxycarbonitride (SiOCN), silicon boronitride (SiBN), silicon oxyboron nitride (SiOBN), or silicon oxycarbide (SiOC), or their combination. It is illustrated that the gate spacer 140 is a single layer, but it is only for convenience of explanation and the present disclosure is not limited thereto.

According to some example embodiments, the gate capping film 145 may be disposed on the first gate electrode 120 and the second gate electrode 220. The upper side of the gate capping film 145 may be the upper side of a gate structure GS. Unlike what is illustrated, the gate capping film 145 may be disposed between the gate spacers 140.

According to some example embodiments, for example, the gate capping film 145 may include at least one of silicon nitride (SiN), silicon oxynitride (SiON), silicon carbonitride (SiCN), or silicon oxycarbonitride (SiOCN), or combinations thereof.

According to some example embodiments, the first source/drain pattern 150 may be disposed in the first activation region AR1. The first source/drain pattern 150 may be disposed on the frontside of the insulation substrate 100FS. The first source/drain pattern 150 may be disposed between the first gate electrode 120 and the second gate electrode 220 that are adjacent in the first direction D1, and between the second gate electrodes 220 that are adjacent to each other. The first source/drain pattern 150 may contact the first active pattern AP1.

According to some example embodiments, the second source/drain pattern 250 may be disposed in the second activation region AR2. The second source/drain pattern 250 may be disposed on the frontside of the insulation substrate 100FS. The second source/drain pattern 250 may be disposed between the first gate electrode 120 and the second gate electrode 220 that are adjacent in the first direction D1, and between the second gate electrodes 220 that are adjacent to each other. The second source/drain pattern 250 may contact the second active pattern AP2.

According to some example embodiments, the first source/drain pattern 150 may be included in the source/drain of a transistor that uses the first active pattern AP1 as a channel region. The second source/drain pattern 250 may be included in the source/drain of a transistor that uses the second active pattern AP2 as a channel region.

According to some example embodiments, each of the first source/drain pattern 150 and the second source/drain pattern 250 may include an epitaxial pattern. Each of the first source/drain pattern 150 and the second source/drain pattern 250 may include a semiconductor material.

According to some example embodiments, the first source/drain pattern 150 and the second source/drain pattern 250 may have different conductivity types. For example, the first source/drain pattern 150 may have N-type conductivity, and the second source/drain pattern 250 may have P-type conductivity. The first source/drain pattern 150 may include an N-type dopant. The N-type dopant may include at least one of phosphorus (P), arsenic (As), antimony (Sb) or bismuth (Bi). However, the present disclosure is not limited thereto. The second source/drain pattern 250 may include a P-type dopant. The P-type dopant may include at least one of boron (B) or gallium (Ga). However, the present disclosure is not limited thereto.

According to some example embodiments, a source/drain etching stopping layer 160 may extend along the outer side wall of the gate spacer 140, the side wall of the first source/drain pattern 150, and the side wall of the second source/drain pattern 250. The source/drain etching stopping layer 160 may extend along the frontside of the field insulation layer 105FS. It is illustrated that the source/drain etching stopping layer 160 extends along the side wall of the gate capping film 145, but the present disclosure is not limited thereto. For example, the source/drain etching stopping layer 160 may not extend along the side wall of the gate capping film 145.

According to some example embodiments, the source/drain etching stopping layer 160 may include at least one of silicon nitride (SiN), silicon oxynitride (SiON), silicon oxycarbonitride (SiOCN), silicon boronitride (SiBN), silicon oxyboron nitride (SiOBN), or silicon oxycarbide (SiOC), or combinations thereof.

According to some example embodiments, a first frontside interlayer insulating film 190 may be disposed on the source/drain etching stopping layer 160. The first frontside interlayer insulating film 190 may be formed on the field insulation layer 105. The first frontside interlayer insulating film 190 may be disposed on the first source/drain pattern 150 and the second source/drain pattern 250.

According to some example embodiments, the first frontside interlayer insulating film 190 may not cover the upper sides of the first gate structure GS1 and the second gate structure GS2. For example, the upper side of the first frontside interlayer insulating film 190 may be coplanar with the upper sides of the first gate structure GS1 and the second gate structure GS2.

According to some example embodiments, for example, the first frontside interlayer insulating film 190 may include at least one of silicon oxide, silicon nitride, silicon oxynitride, or low-k dielectric material. For example, the low-k dielectric material may contain Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), oxane (DADBS), TriMethylSilil Phosphate (TMSP), PolyTetraFluoroEthylene (PTFE), Tonen SilaZen (TOSZ), Fluoride Silicate Glass (FSG), polyimide nanofoams such as polypropylene oxide, carbon doped silicon oxide (CDO), organo silicate glass (OSG), SiLK, Amorphous Fluorinated Carbon, silica aerogels, silica xerogels, or mesoporous silica, or any combination thereof. However, the present disclosure is not limited thereto.

According to some example embodiments, the frontside source/drain contact 170 may be disposed on the first source/drain pattern 150 and the second source/drain pattern 250 on the frontside of the insulation substrate 100FS. The frontside source/drain contact 170 may be connected to the first source/drain pattern 150 and the second source/drain pattern 250. The frontside source/drain contact 170 may electrically connect the first source/drain pattern 150 and the second source/drain pattern 250. The frontside source/drain contact 170 may pass the source/drain etching stopping layer 160, and be connected to the first source/drain pattern 150 and the second source/drain pattern 250.

According to some example embodiments, the frontside source/drain contact 170 may be disposed on the first gate electrode 120 that overlaps the backside gate contact 280 in the third direction D3 and the first source/drain pattern 150 that is closest in the first direction D1. The frontside source/drain contact 170 may be connected to the first gate electrode 120, which may be connected to the backside gate contact 280, and the first source/drain pattern 150, which is closest in the first direction D1.

According to some example embodiments, the frontside source/drain contact 170 may be disposed in the first frontside interlayer insulating film 190. The frontside source/drain contact 170 may be surrounded by the first frontside interlayer insulating film 190. The first frontside interlayer insulating film 190 does not cover the upper side of the frontside source/drain contact 170. In an example embodiment, the upper side of the frontside source/drain contact 170 may not protrude above the upper side of the gate structure GS. The upper side of the frontside source/drain contact 170 may be coplanar with the upper sides of the first gate structure GS1 and the second gate structure GS2. Unlike what is illustrated, in another example embodiment, the upper side of the frontside source/drain contact 170 may protrude above the upper sides of the first gate structure GS1 and the second gate structure GS2.

According to some example embodiments, a contact silicide layer 155 may be disposed between the frontside source/drain contact 170 and the first source/drain pattern 150. It is illustrated that the contact silicide layer 155 is formed along the profile of the interface between the first source/drain pattern 150 and the frontside source/drain contact 170. However, it is merely for convenience of explanation and the present disclosure is not limited thereto. For example, the contact silicide layer 155 may include a metal silicide material.

According to some example embodiments, the frontside source/drain contact 170 may include a frontside source/drain contact barrier film 170a and a frontside source/drain contact filling layer 170b on the frontside source/drain contact barrier film 170a. The frontside source/drain contact barrier film 170a may extend along a side wall and a bottom surface of the frontside source/drain contact filling layer 170b.

FIGS. 1 and 5 illustrate that the frontside source/drain contact 170 extends in the second direction D2 across the first activation region AR1, the second activation region AR2 and the field region FR. However, the present disclosure is not limited thereto. For example, the frontside source/drain contact 170 may be connected to the first source/drain pattern 150 in the first activation region AR1 and may not extend to the field region FR and the second activation region AR2. In another example embodiment, the frontside source/drain contact 170 may be connected to the second source/drain pattern 250 in the second activation region AR2 and may not extend to the first activation region AR1.

According to some example embodiments, it is illustrated that relative to the frontside of the insulation substrate 100FS, the upper side of the frontside source/drain contact barrier film 170a may be located at substantially the same height as the upper side of the frontside source/drain contact filling layer 170b, but the present disclosure is not limited thereto. Relative to the frontside of the insulation substrate 100FS, the upper side of the frontside source/drain contact barrier film 170a may be lower than the upper side of the frontside source/drain contact filling layer 170b.

According to some example embodiments, for example, the frontside source/drain contact barrier film 170a may include at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), Tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh) or a 2D material. According to some example embodiments, in a semiconductor device, the 2D material may be a metallic material and/or a semiconductor material. The 2D material may include a 2D allotrope or a 2D compound. For example, at least one of graphene, molybdenum disulfide (MoS2), molybdenum diselenide (MoSe2), tungsten diselenide (WSe2), or tungsten disulfide (WS2) may be included, but the present disclosure is not limited thereto. In other words, the 2D materials described herein are mere examples, and thus 2D materials that may be included in the semiconductor device are not limited to the materials described herein.

According to some example embodiments, the frontside source/drain contact filling layer 170b may include, for example, at least one of aluminum (Al), tungsten (W), cobalt (Co), ruthenium (Ru), silver (Ag), gold (Au), manganese (Mn) or molybdenum (Mo).

According to some example embodiments, it is illustrated that the frontside source/drain contact 170 includes a plurality of conductive films, but the preset disclosure is not limited thereto. Unlike what is illustrated, the frontside source/drain contact 170 may be a single layer.

According to some example embodiments, the first backside source/drain contact 270 and the second backside source/drain contact 370 may be disposed on the first source/drain pattern 150 and the second source/drain pattern 250 on the backside of the insulation substrate 100BS. The first backside source/drain contact 270 and the second backside source/drain contact 370 may be connected to the first source/drain pattern 150 and the second source/drain pattern 250 by penetrating the backside of the insulation substrate 100BS.

According to some example embodiments, the first backside source/drain contact 270 may extend in the second direction D2 across the first activation region AR1, the second activation region AR2 and the field region FR. The first backside source/drain contact 270 may contact the first source/drain pattern 150 and the second source/drain pattern 250. For example, the first backside source/drain contact 270 may contact a backside of the first source/drain pattern 150 and a backside of the second source/drain pattern 250.

According to some example embodiments, the first backside source/drain contact 270 may include a contact part 271 and a via connecting part 272.

According to some example embodiments, the contact part 271 may be disposed on the via connecting part 272. The contact part 271 may extend from the via connecting part 272 toward the backside of the first source/drain pattern 150 or the backside of the second source/drain pattern 250 in the third direction D3. The contact part 271 may be in direct contact with the backside of the first source/drain pattern 150 or the backside of the second source/drain pattern 250. The contact part 271 may overlap the first source/drain pattern 150 or the second source/drain pattern 250 in the third direction D3. A portion of the contact part 271 may be disposed in the first source/drain pattern 150 or the second source/drain pattern 250. At least a portion of the via connecting part 272 may be surrounded by the insulation substrate 100. For example, an upper portion of the via connecting part 272 may be surrounded by the insulation substrate 100. At least a portion of the contact part 271 may be surrounded by the insulation substrate 100. For example, a lower portion of the contact part 271 may be surrounded by the insulation substrate 100.

According to some example embodiments, the via connecting part 272 may be disposed between the contact part 271 and the backside wiring via 275. The via connecting part 272 may connect the contact part 271 and the backside wiring via 275. The via connecting part 272 may penetrate the first backside interlayer insulating film 290. The via connecting part 272 may penetrate the backside of the insulation substrate 100BS. The via connecting part 272 may extend in the second direction D2 across the first activation region AR1, the second activation region AR2 and the field region FR.

According to some example embodiments, the first backside source/drain contact 270 may be connected to the first backside wiring line 310 through the backside wiring via 275. The first source/drain pattern 150 or the second source/drain pattern 250 may be electrically connected to the first backside wiring line 310 through the first backside source/drain contact 270 and the backside wiring via 275.

According to some example embodiments, the second backside source/drain contact 370 may be disposed on either the first activation region AR1 or the second activation region AR2. For example, the single second backside source/drain contact 370 may overlap the first source/drain pattern 150 of the first activation region AR1 in the third direction D3, and may not overlap the second source/drain pattern 250 in the second activation region AR2 in the third direction D3. Another single second backside source/drain contact 370 may overlap the second source/drain pattern 250 in the second activation region AR2 in the third direction D3, and may not overlap the first source/drain pattern 150 of the first activation region AR1 in the third direction D3.

According to some example embodiments, the second backside source/drain contact 370 may be connected to the second backside wiring line 320 through the backside wiring via 275. The first source/drain pattern 150 or the second source/drain pattern 250 may be electrically connected to the second backside wiring line 320 through the second backside source/drain contact 370 and the backside wiring via 275.

According to some example embodiments, like the first backside source/drain contact 270, the second backside source/drain contact 370 may include a contact part and a via connecting part. Meanwhile, the via connecting part of the second backside source/drain contact 370 may not extend in the second direction D2 across the first activation region AR1, the second activation region AR2 and the field region FR, but may overlap any one of the first activation region AR1 and the second activation region AR2 in the third direction D3.

Description of the second backside source/drain contact 370 is substantially the same as the description of the first backside source/drain contact 270, and thus description of the second backside source/drain contact 370 is omitted.

According to some example embodiments, a first frontside etching stopping layer 196 may be disposed on the first frontside interlayer insulating film 190, the first gate structure GS1 and the second gate structure GS2, and the frontside source/drain contact 170. A second frontside interlayer insulating film 191 may be disposed on the first frontside etching stopping layer 196.

According to some example embodiments, the first frontside etching stopping layer 196 may include a material having etch selectivity to the second frontside interlayer insulating film 191. For example, the first frontside etching stopping layer 196 may include, for example, at least one of silicon nitride (SiN), silicon oxynitride (SiON), silicon oxycarbonitride (SiOCN), silicon boronitride (SiBN), silicon oxyboron nitride (SiOBN), silicon oxycarbide (SiOC), aluminum oxide (AlO), aluminum nitride (AlN), or aluminum oxycarbide (AlOC), or combinations thereof. It is illustrated that the first frontside etching stopping layer 196 is a single layer, but the present disclosure is not limited thereto. Unlike what is illustrated, the first frontside etching stopping layer 196 may not be formed. For example, the second frontside interlayer insulating film 191 may include at least one of silicon oxide, silicon nitride, silicon carbonitride, silicon oxynitride, or low-k dielectric material.

According to some example embodiments, a second frontside etching stopping layer 197 may be disposed between the second frontside interlayer insulating film 191 and a third frontside interlayer insulating film 192. The second frontside etching stopping layer 197 may extend along the upper side of the second frontside interlayer insulating film 191.

According to some example embodiments, the second frontside etching stopping layer 197 may include a material having etch selectivity to the third frontside interlayer insulating film 192. Description on the substances included in the second frontside etching stopping layer 197 may be substantially the same as the description of the first frontside etching stopping layer 196. Description on the third frontside interlayer insulating film 192 may be substantially the same as the description of the second frontside interlayer insulating film 191.

According to some example embodiments, the frontside gate contact 180 may be disposed on the second gate electrode 220 on the frontside of the insulation substrate 100FS. The frontside gate contact 180 may penetrate the gate capping film 145 and be connected to the second gate electrode 220. The frontside gate contact 180 may penetrate the first frontside etching stopping layer 196 and the second frontside interlayer insulating film 191. The frontside gate contact 180 may be connected to the frontside wiring line 205.

In an example embodiment, the upper side of the frontside gate contact 180 may protrude the upper sides of the first gate structure GS1 and the second gate structure GS2. Unlike what is illustrated, in another example embodiment, the upper side of the frontside gate contact 180 may be coplanar with the upper sides of the first gate structure GS1 and the second gate structure GS2.

According to some example embodiments, the frontside gate contact 180 may include a frontside gate contact barrier film 180a and a frontside gate contact filling layer 180b on the frontside gate contact barrier film 180a. Description of the materials included in the frontside gate contact barrier film 180a and the frontside gate contact filling layer 180b may be the same as the description of the materials included in the frontside source/drain contact barrier film 170a and the frontside source/drain contact filling layer 170b.

According to some example embodiments, the backside gate contact 280 may be disposed in the field region FR. The backside gate contact 280 may be connected to the first gate electrode 120 by penetrating the backside of the insulation substrate 100BS. The backside gate contact 280 may penetrate the first backside interlayer insulating film 290 and the insulation substrate 100. The backside gate contact 280 penetrate the backside of the insulation substrate 100BS and have an upper surface disposed in the field insulation layer 105. The backside gate contact 280 may be connected to the first backside wiring line 310 through the backside wiring via 275. In other words, the first gate electrode 120 may be connected to the first backside wiring line 310 through the backside gate contact 280 and the backside wiring via 275.

According to some example embodiments, in the first direction D1, the width of the backside gate contact 280 may be larger than the width of the protruding part 122b. In the second direction D2, the width of the frontside of the backside gate contact 280FS in contact with the protruding part 122b may be the same as the width of the bottom surface of the protruding part 122b. For example, in the second direction D2, the width of the frontside of the backside gate contact 280FS may be the same as the width of the bottom surface of the first filling conductive film 122BS, which may be the bottom surface of the protruding part 122b.

FIGS. 3 and 4 illustrate that the backside gate contact 280 is a single layer, but the present disclosure is not limited thereto. For example, the backside gate contact 280 may include a barrier film and a filling layer like the frontside gate contact 180.

According to some example embodiments, the first backside interlayer insulating film 290, a first backside etching stopping layer 296, a second backside interlayer insulating film 291, a second backside etching stopping layer 297 and a third backside interlayer insulating film 292 may be disposed on the backside of the insulation substrate 100BS. Descriptions on the first backside interlayer insulating film 290, the first backside etching stopping layer 296, the second backside interlayer insulating film 291, the second backside etching stopping layer 297 and the third backside interlayer insulating film 292 may be the same as the descriptions on the first frontside interlayer insulating film 190, the first frontside etching stopping layer 196, the second frontside interlayer insulating film 191, the second frontside etching stopping layer 197 and the third frontside interlayer insulating film 192, and thus the descriptions are omitted.

According to some example embodiments, the frontside wiring via 175 may be disposed in the second frontside interlayer insulating film 191. The frontside wiring via 175 may penetrate the first frontside etching stopping layer 196 and may be directly connected to the frontside source/drain contact 170. The frontside wiring via 175 may connect the frontside source/drain contact 170 and the frontside wiring line 205.

According to some example embodiments, the frontside wiring via 175 may include a frontside via barrier film 175a and a frontside via filling layer 175b. The frontside via barrier film 175a may extend along a side wall and a bottom surface of the frontside via filling layer 175b. For example, the frontside via barrier film 175a may include at least one of tantalum (Ta), tantalum nitride (TaN), titanium (Ti), titanium nitride (TiN), titanium silicon nitride (TiSiN), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh) or a 2D material. For example, the frontside via filling layer 175b may include at least one of aluminum (Al), tungsten (W), cobalt (Co), ruthenium (Ru), copper (Cu), silver (Ag), gold (Au), manganese (Mn), or molybdenum (Mo).

According to some example embodiments, the frontside wiring line 205 may be disposed in the third frontside interlayer insulating film 192. The frontside wiring line 205 may be connected to the frontside gate contact 180. The frontside wiring line 205 may be connected to the frontside source/drain contact 170 through the frontside wiring via 175.

According to some example embodiments, the frontside wiring line 205 may include a frontside wiring barrier film 205a and a frontside wiring filling layer 205b. For example, the frontside wiring barrier film 205a may include at least one of metal, conductive metal nitride, conductive metal carbide, conductive metal oxide, conductive metal carbonitride, or a 2D material. For example, the frontside wiring filling layer 205b may include at least one of metal or metal alloy. Description of the frontside wiring barrier film 205a and the frontside wiring filling layer 205b of the frontside wiring line 205 may be substantially the same as the description on the frontside via barrier film 175a and the frontside via filling layer 175b of the frontside wiring via 175. It is illustrated that the frontside wiring line 205 has a multi-conductive film structure, but the present disclosure is not limited thereto. Unlike what is illustrated, the frontside wiring line 205 may have a single conductive film structure.

According to some example embodiments, the backside wiring via 275 may be disposed in the second backside interlayer insulating film 291. The backside wiring via 275 may be connected to the backside gate contact 280, the first backside source/drain contact 270 and the second backside source/drain contact 370. For example, each backside wiring via 275 may overlap the backside gate contact 280, the first backside source/drain contact 270 and the second backside source/drain contact 370, respectively, in the third direction D3.

According to some example embodiments, the backside wiring via 275 may include a backside via barrier film 275a and a backside via filling layer 275b. The backside via barrier film 275a may extend along a side wall and a bottom surface of the backside via filling layer 275b. Description of the backside wiring via 275 is substantially the same as the description of the frontside wiring via 175, and thus description of the backside wiring via 275 is omitted.

According to some example embodiments, the first backside wiring line 310 and the second backside wiring line 320 may be disposed on the backside of the insulation substrate 100BS. The first backside wiring line 310 may be connected to the backside gate contact 280. The second backside wiring line 320 may be connected to the first backside source/drain contact 270 and the second backside source/drain contact 370.

According to some example embodiments, the first backside wiring line 310 may be disposed in the field region FR. The first backside wiring line 310 may overlap the field insulation layer 105 in the third direction D3. The second backside wiring line 320 may overlap the first activation region AR1 and the second activation region AR2 in the third direction D3. Therefore, the second backside wiring line 320 may not overlap the field insulation layer 105 in the third direction D3. A plurality of second backside wiring lines 320 may be spaced apart from each other in the second direction D2 and extend in the first direction D1.

For example, the first backside wiring line 310 may electrically transmit data signals regarding the semiconductor device. The second backside wiring line 320 may electrically transmit power signals regarding the semiconductor device.

In the existing technology, a wiring line that electrically transmits data signals regarding a semiconductor device may be disposed on a frontside of an insulation substrate and connected to a gate electrode. In the semiconductor device according to some example embodiments, by including the first backside wiring line 310 on the backside of the insulation substrate 100BS rather than the frontside of the insulation substrate 100FS, pitch of the frontside wiring line 205 disposed on the frontside of the insulation substrate 100FS may be increased. Therefore, the electrical resistance and capacitance of the frontside wiring line 205 may be reduced, improving the electrical reliability of the semiconductor device.

Meanwhile, in an implementation in which the wiring line is disposed on the backside of the semiconductor device, the pitch of the remaining frontside wiring line may be maintained, and the area of the semiconductor device may be reduced. For example, in a semiconductor device with a reduced number of frontside wiring lines may be formed. The frontside wiring lines may have a pitch that may be easy to design. The semiconductor device including a backside wiring line may have a reduced cell height, and the semiconductor device may be downsized. For example, the semiconductor device may have a reduced frontside wiring structure and the cell height may be reduced.

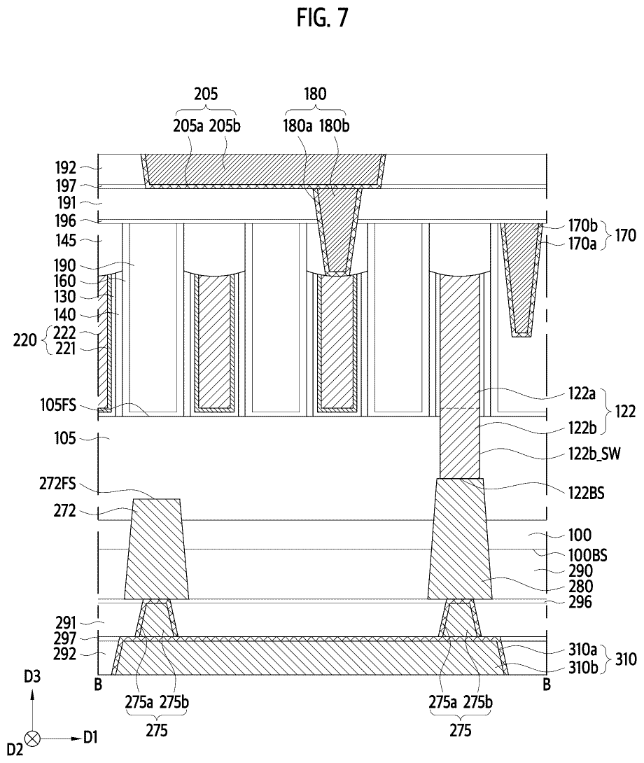

FIG. 7 is a diagram for explaining a semiconductor device according to an example embodiment. For convenience of explanation, description will focus on differences from those described with reference to FIGS. 1 to 6.

Referring to FIG. 7, relative to the backside of the insulation substrate 100BS, the bottom surface of the protruding part 122b may be disposed above the frontside of the via connecting part 272FS. In other words, relative to the backside of the insulation substrate 100BS, the bottom surface of the first filling conductive film 122BS, which may be the bottom surface of the protruding part 122b, may be disposed on a higher plane than the frontside of the via connecting part 272FS. Relative to the frontside of the field insulation layer 105FS, the bottom surface of the first filling conductive film 122BS may have a smaller depth than the frontside of the via connecting part 272FS.

According to some example embodiments, relative to the backside of the insulation substrate 100BS, the bottom surface of the protruding part 122b may be disposed above the frontside of the via connecting part of the second backside source/drain contact 370 in FIG. 2. When the bottom surface of the protruding part 122b is disposed below the frontside of the via connecting part 272FS relative to the backside of the insulation substrate 100BS, the degree of overlap between the via connecting part 272 in FIG. 2 of the first backside source/drain contact 270 of FIG. 2 and the second backside source/drain contact 370 and the protruding part 122b in the first direction D1 may be increased, and the resistance occurring between the protruding part 122b and the via connecting part 272 in FIG. 2 of the first backside source/drain contact 270 of FIG. 2 and the second backside source/drain contact 370 may increase. Therefore, when the bottom surface of the protruding part 122b is disposed above the frontside of the via connecting part 272FS relative to the backside of the insulation substrate 100BS, electrical interference due to resistance may be reduced, and the backside gate contact 280 may be formed subsequently.

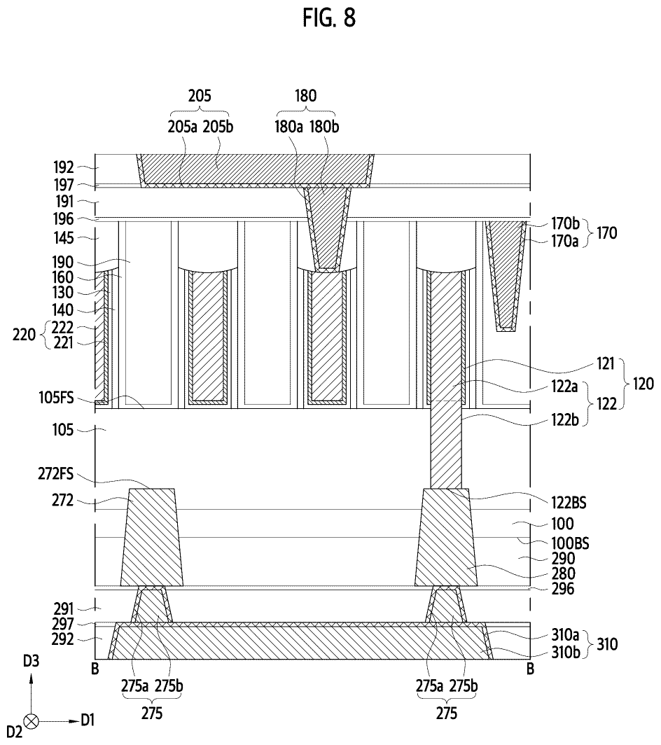

FIG. 8 is a diagram for explaining a semiconductor device according to another example embodiment. For convenience of explanation, differences from those described with reference to FIGS. 1 to 6 will be mainly described.

Referring to FIG. 8, in the field region FR, the first electrode layer 121 may cover the side wall of the extension part 122a. In the field region FR, the first electrode layer 121 may cover the side wall of a portion of the extension part 122a that overlaps the protruding part 122b in the third direction D3. The first electrode layer 121 may overlap the extension part 122a in the field region FR in the first direction D1. For example, in the field region FR, the first electrode layer 121 may be disposed between the side wall of the extension part 122a and the gate insulating film 130. The first electrode layer 121 on the field insulation layer 105 may extend in the third direction D3 along the side wall of the extension part 122a.

Even in this case, in the field region FR, the width of the extension part 122a and the width of the protruding part 122b may be the same in the first direction D1. Meanwhile, in the field region FR, the width of the first gate electrode 120 disposed on the frontside of the field insulation layer 105FS in the first direction D1 and the width of the first gate electrode 120 overlapping the field insulation layer 105 in the first direction D1 may be different. Specifically, a portion of the first gate electrode 120 that is disposed on the frontside of the field insulation layer 105FS and does not overlap the field insulation layer 105 in the first direction D1 may include the extension part 122a and the first electrode layer 121. Further, a portion of the first gate electrode 120 surrounded by the field insulation layer 105 and overlapping the field insulation layer 105 in the first direction D1 may include only the protruding part 122b and may not include the first electrode layer 121. Therefore, in the field region FR, the width of the first gate electrode 120 disposed on the frontside of the field insulation layer 105FS in the first direction D1 may be greater than the width of the first gate electrode 120 overlapping the field insulation layer 105 in the first direction D1.

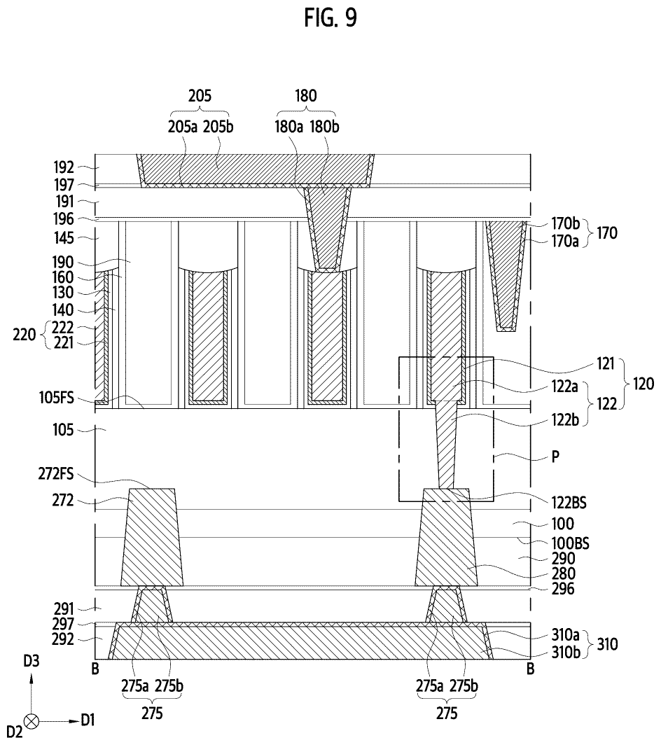

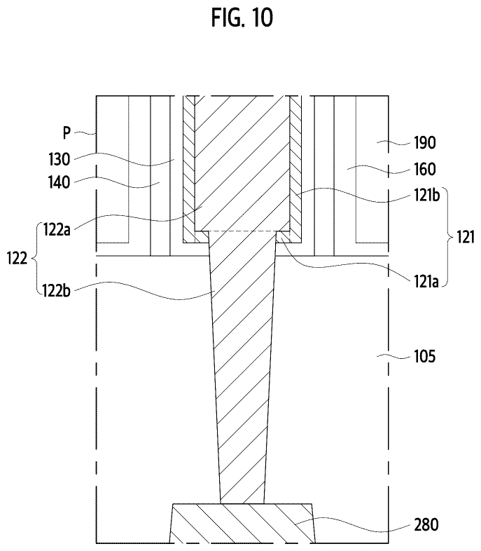

FIG. 9 is a diagram for explaining a semiconductor device according to another example embodiment. FIG. 10 is an enlarged view illustrating the part P of FIG. 9. For convenience of explanation, differences from those described with reference to FIGS. 1 to 6 will be mainly described.

Referring to FIG. 9 and FIG. 10, in the first direction D1, the width of the protruding part 122b may decrease as the protruding part 122b approaches the backside of the insulation substrate 100BS. The width of the protruding part 122b may be smaller than the width of the extension part 122a in the first direction D1. Depending on the process of forming the protruding part 122b, the protruding part 122b may have a shape in which the side wall is inclined.

According to some example embodiments, in the field region FR, the first electrode layer 121 may overlap the extension part 122a in the first direction D1. In the field region FR, the first electrode layer 121 may include a bent part 121a and a side wall part 121b.

According to some example embodiments, the bent part 121a may be bent from the side wall part 121b. For example, the bent part 121a may be bent from the side wall part 121b to be disposed below the extension part 122a. The bent part 121a may surround a portion of the side wall of the protruding part 122b on the gate insulating film 130.

According to some example embodiments, the side wall part 121b may be disposed on the side wall of the extension part 122a. The side wall part 121b may extend in the third direction D3 along the side wall of the extension part 122a. In the first direction D1, the side wall part 121b may be disposed between the extension part 122a and the gate insulating film 130.

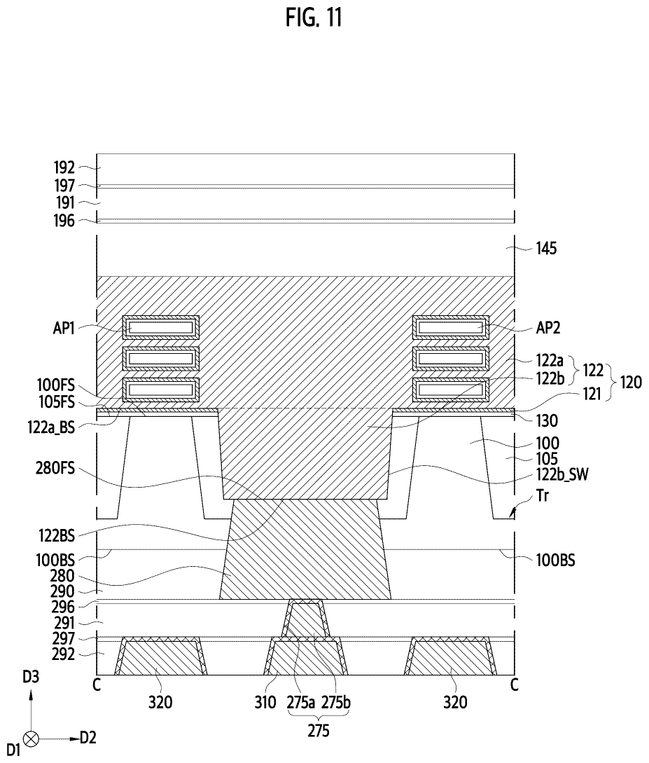

FIG. 11 is a diagram for explaining a semiconductor device according to another example embodiment. For convenience of explanation, differences from those described with reference to FIGS. 1 to 6 will be mainly described.

Referring to FIG. 11, in the second direction D2, the width of the bottom surface of the protruding parts 122b that contact the frontside of the backside gate contact 280FS may be larger than the width of the frontside of the backside gate contact 280FS that contact the bottom surface of the protruding parts 122b. For example, in the second direction D2, the width of the bottom surface of the first filling conductive film 122BS, which may be the bottom surface of the protruding part 122b, may be larger than the width of the frontside of the backside gate contact 280FS. In the second direction D2, the width of the backside gate contact 280 may be smaller than the width of the protruding part 122b. In the second direction D2, the width of the frontside of the backside gate contact 280FS may be smaller than the width of the field insulation layer 105.

According to some example embodiments, in the second direction D2, when the width of the backside gate contact 280 is larger than the width of the protruding part 122b, the backside gate contact 280 may overlap the first activation region AR1 or the second activation region AR2 in the third direction D3. In this case, electrical interference may occur in the first active pattern AP1 or the second active pattern AP2 due to the backside gate contact 280. Therefore, in order for the protruding part 122b and the backside gate contact 280 to be stably insulated from the first activation region AR1 and the second activation region AR2 by the field insulation layer 105, the width of the backside gate contact 280 may be formed to be smaller than the width of the protruding part 122b in the second direction D2.

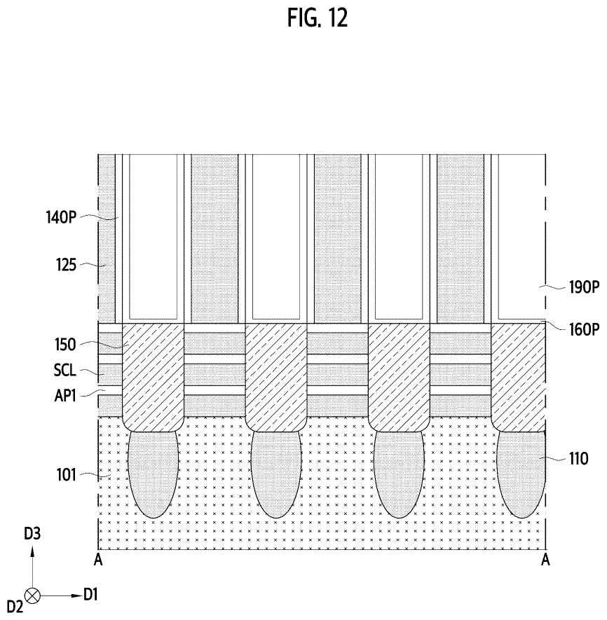

FIGS. 12 to 38 are diagrams for explaining a method of manufacturing a semiconductor device according to some example embodiments.

Referring to FIG. 12, the first active pattern AP1 and a sacrificial layer SCL may be alternately stacked on a sacrificial substrate 101 on which the supporter 110 is formed. A sacrificial gate pattern 125 and a pre gate spacer 140P may be formed on the first active pattern AP1.

For example, the sacrificial substrate 101 may include a semiconductor material. The sacrificial substrate 101 may be a silicon substrate or a silicon-on-insulator (SOI). Alternatively, the sacrificial substrate 101 may include silicon-germanium, silicon germanium on insulator (SGOI), indium antimonide, lead tellurium compound, indium arsenide, indium phosphide, gallium arsenide, or gallium antimonide. However, the present disclosure is not limited thereto.

For example, the sacrificial gate pattern 125 may include polysilicon, but the sacrificial gate pattern 125 is not limited thereto. For example, the first active pattern AP1 may include a silicon film.

Further, by patterning the first active pattern AP1 and the sacrificial layer SCL stacked alternately using the sacrificial gate pattern 125 and the pre gate spacer 140P as masks, a trench may be formed on the sacrificial substrate 101. The first source/drain pattern 150 may be formed within the trench. The trench in which the first source/drain pattern 150 is formed may be formed on the supporter 110. A pre source/drain etching stopping layer 160P and a first pre frontside interlayer insulating film 190P may be formed on the first source/drain pattern 150 between the pre gate spacers 140P.

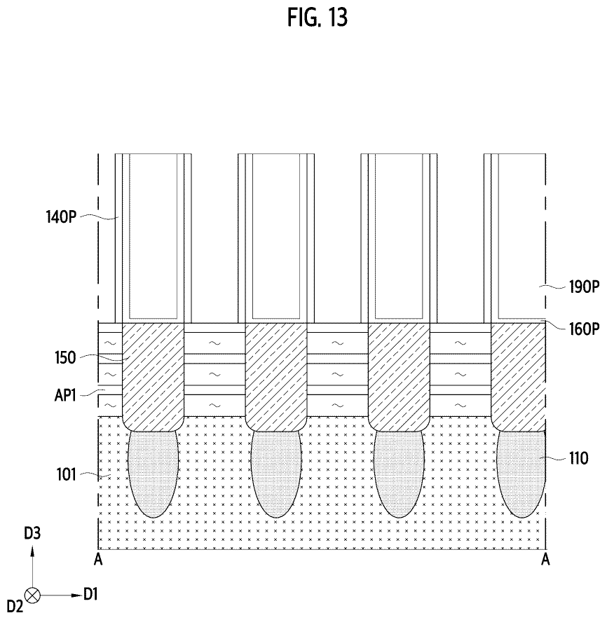

Further, referring to FIG. 13, the sacrificial layer SCL in FIG. 12 and the sacrificial gate pattern 125 in FIG. 12 may be removed. Accordingly, the upper and lower sides of the first active pattern AP1 may be exposed between the first source/drain patterns 150 and a side wall of the pre gate spacer 140P may be exposed.

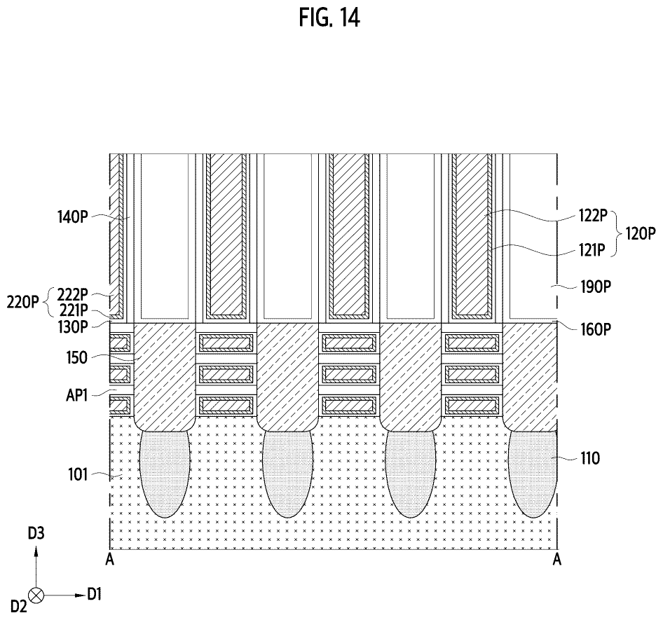

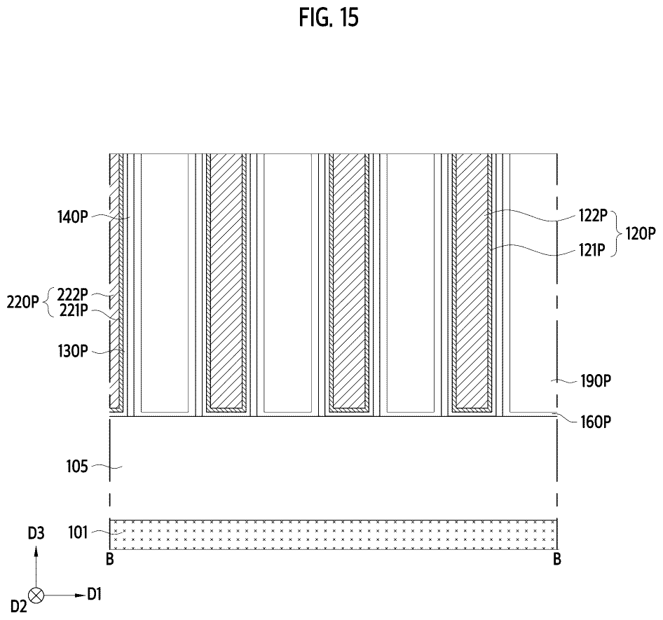

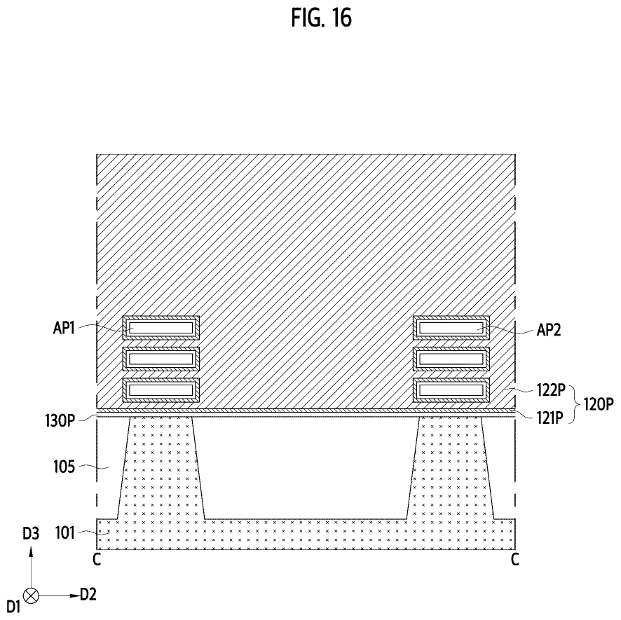

Further, referring to FIG. 14, FIG. 15, and FIG. 16, a pre gate insulating film 130P, a first pre gate electrode 120P and a second pre gate electrode 220P may be formed. The pre gate insulating film 130P and the first pre gate electrode 120P or the pre gate insulating film 130P and the second pre gate electrode 220P may be formed to surround the first active pattern AP1 and the second active pattern AP2. A pre gate insulating film 130P may be formed between the pre gate spacers 140P, and the first pre gate electrode 120P or the second pre gate electrode 220P may be formed on the pre gate insulating film 130P.

According to some example embodiments, a first pre work function adjustment film 121P and a first prefilling conductive film 122P may be formed sequentially on the pre gate insulating film 130P, and thus the first pre gate electrode 120P may be formed. Likewise, a second pre work function adjustment film 221P and a second prefilling conductive film 222P may be formed sequentially on the pre gate insulating film 130P, and the second pre gate electrode 220P may be formed.

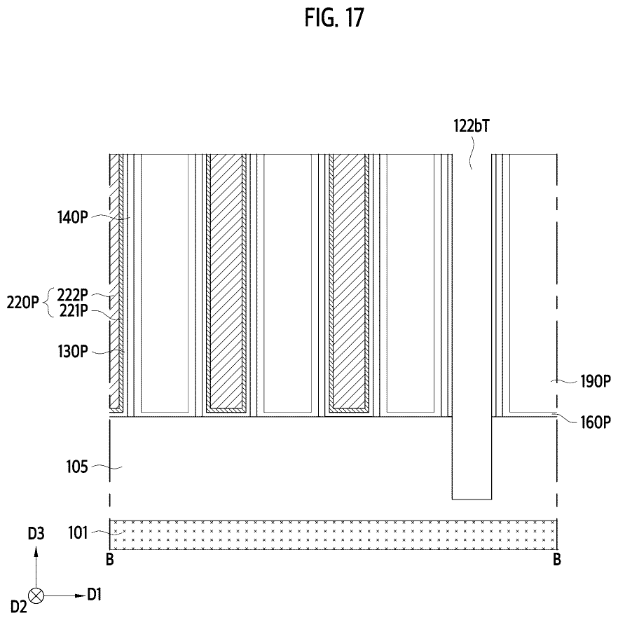

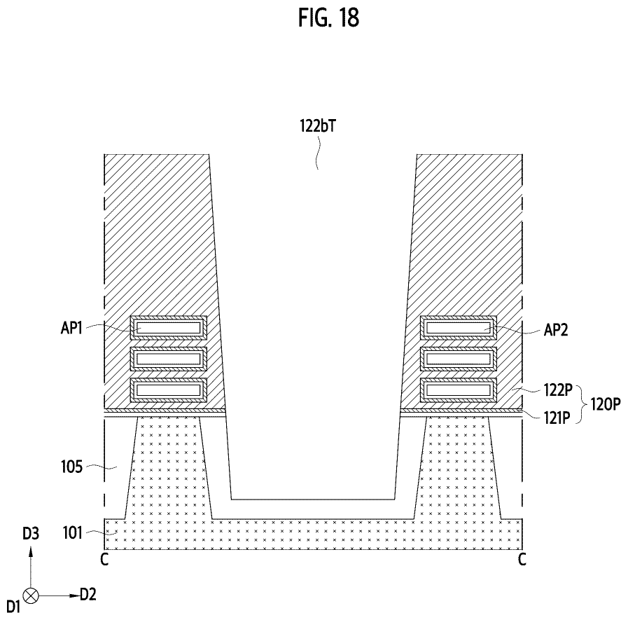

Further, referring to FIG. 17 and FIG. 18, a trench 122bT of the protruding part may be formed on the field insulation layer 105. The trench 122bT of the protruding part may be formed in the field region FR in FIG. 1. The trench 122bT of the protruding part may be formed by removing a portion of the first pre gate electrode 120P in the field region FR in FIG. 1. The trench 122bT of the protruding part may cut the first pre work function adjustment film 121P and the first prefilling conductive film 122P in the second direction D2. In the cross-sectional view cut along the second direction D2, the trench 122bT of the protruding part may penetrate the first pre work function adjustment film 121P and the first prefilling conductive film 122P. The trench 122bT of the protruding part may expose the field insulation layer 105.

According to some example embodiments, as the trench 122bT of the protruding part is formed in the field region FR in FIG. 1, the first pre work function adjustment film 121P and the first prefilling conductive film 122P may be removed between the pre gate insulating films 130P.

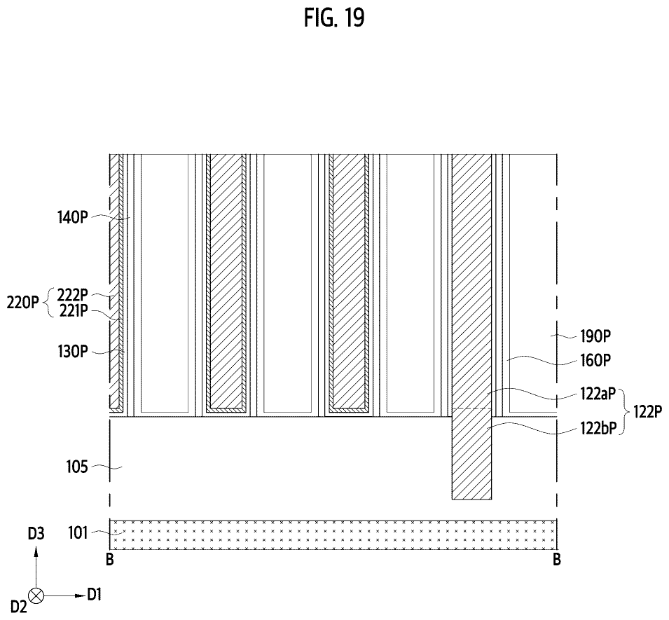

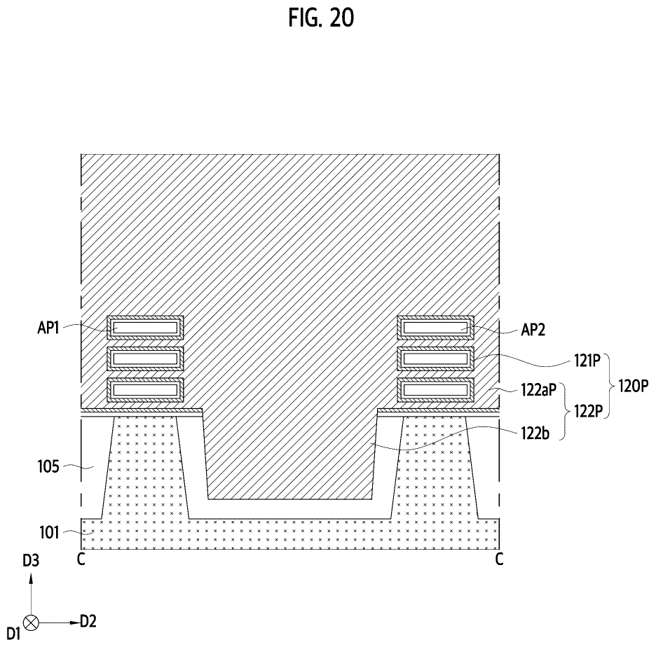

Further, referring to FIG. 19 and FIG. 20, the first prefilling conductive film 122P may be formed within the trench 122bT in FIG. 17 and FIG. 18 of the protruding part. While the first prefilling conductive film 122P fills the trench 122bT in FIG. 17 and FIG. 18 of the protruding part, a pre extension part 122aP disposed on the first pre work function adjustment film 121P and the protruding part 122b protruding from the pre extension part 122aP toward the field insulation layer 105 may be formed.

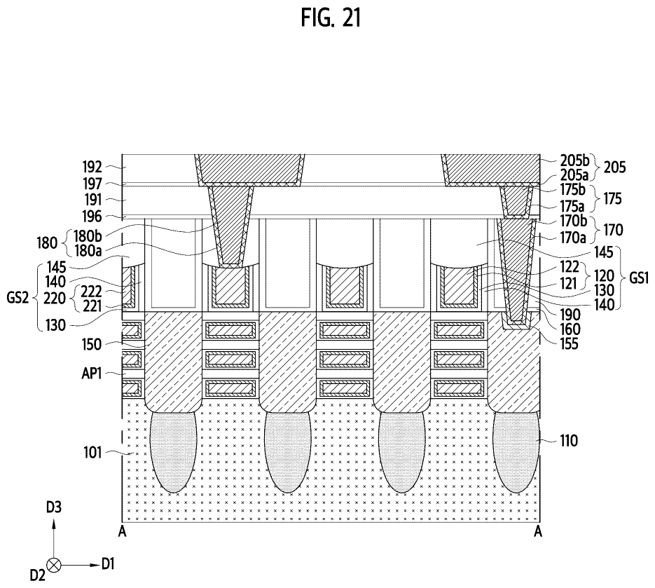

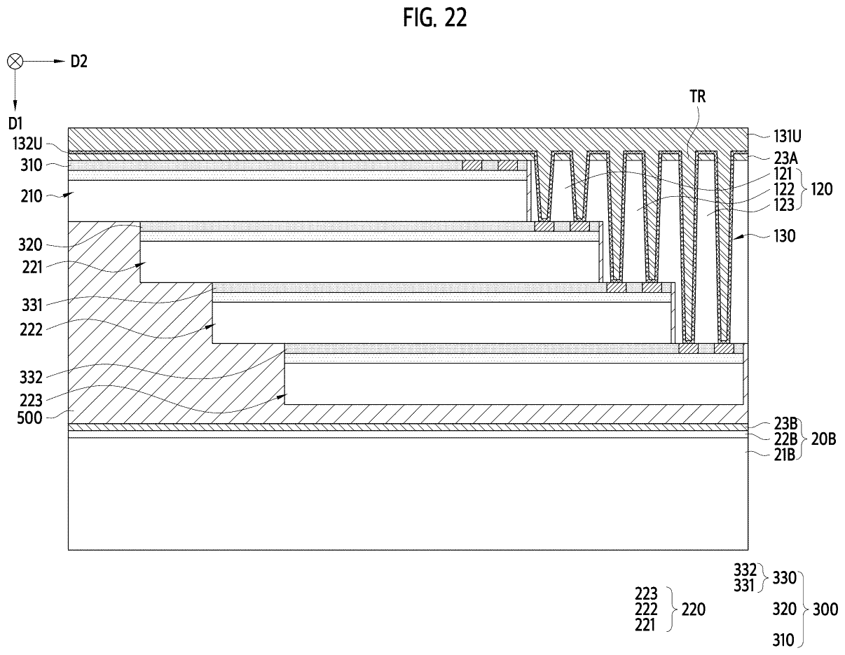

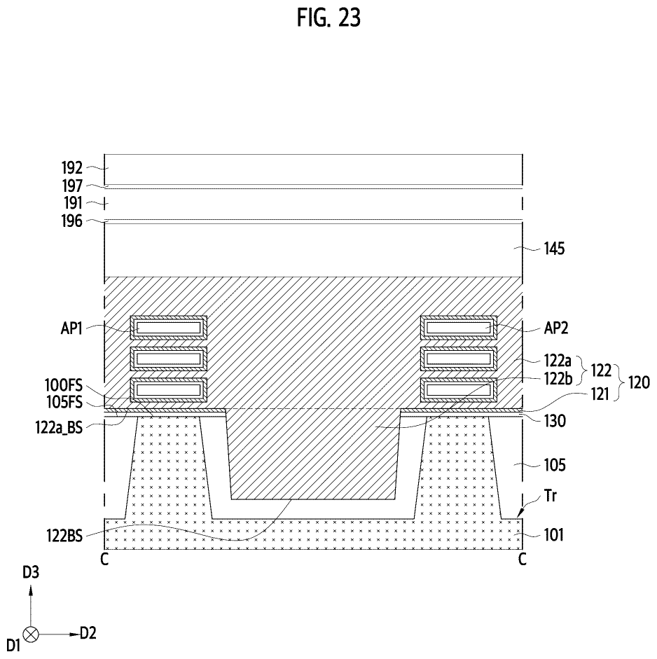

Further, referring to FIG. 21, FIG. 22, and FIG. 23, the gate capping film 145 is formed, so that the first gate structure GS1 and the second gate structure GS2 may be formed. On the first gate structure GS1 and the second gate structure GS2 and the first frontside interlayer insulating film 190, the first frontside etching stopping layer 196, the second frontside interlayer insulating film 191, the second frontside etching stopping layer 197 and the third frontside interlayer insulating film 192 may be formed. The frontside source/drain contact 170 and the frontside wiring via 175 may be formed on the first source/drain pattern 150, and the frontside gate contact 180 may be formed on the second gate electrode 220. The frontside wiring line 205 may be formed on the frontside wiring via 175 and the frontside gate contact 180.

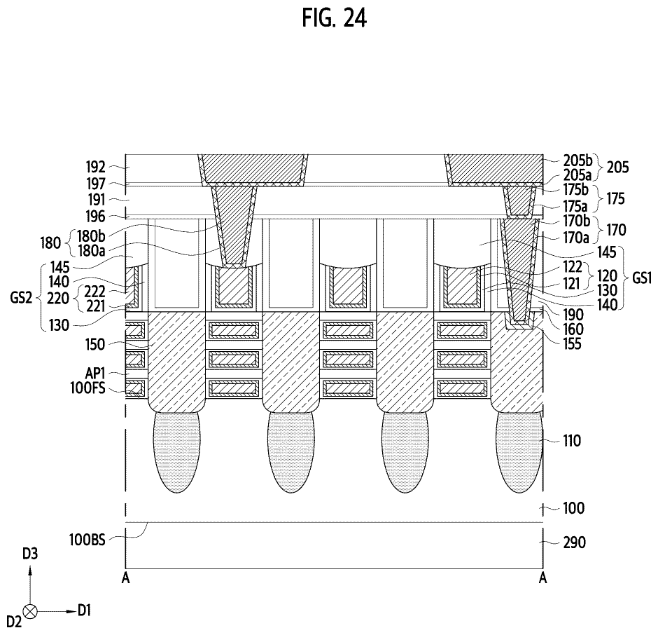

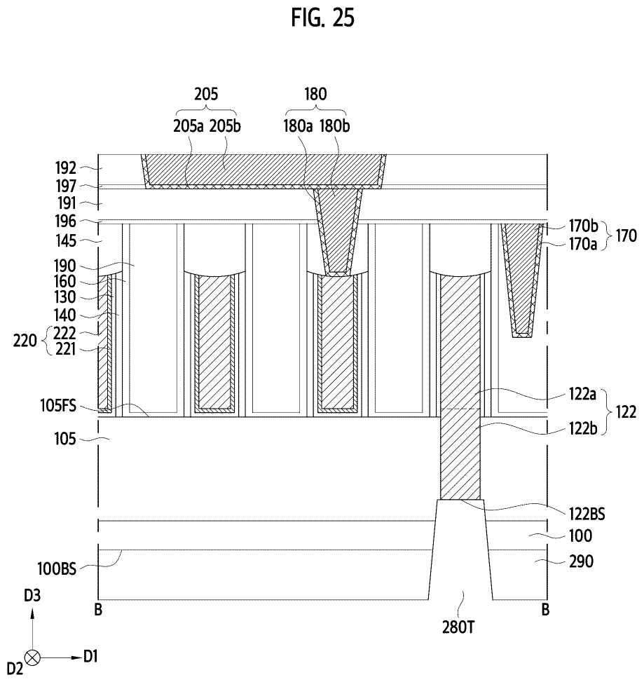

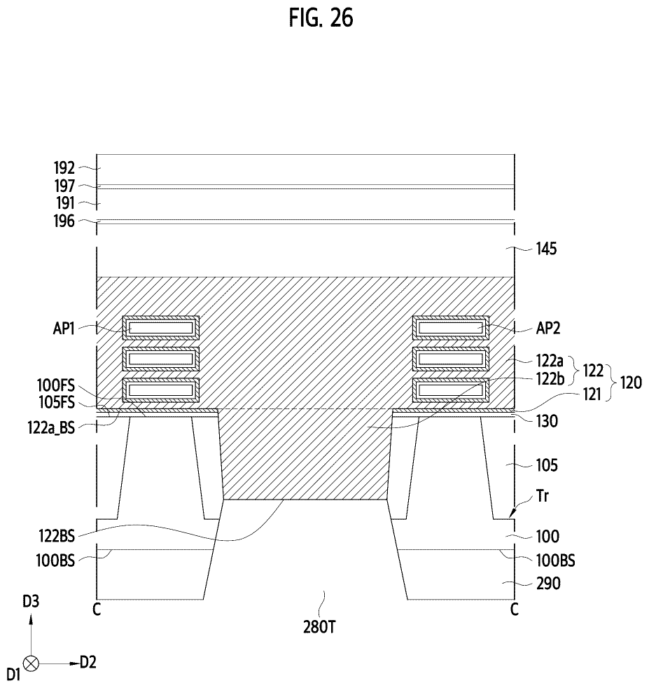

Further, referring to FIG. 24, FIG. 25, and FIG. 26, the sacrificial substrate 101 of FIGS. 21 to 23 may be removed and the insulation substrate 100 may be formed. The first backside interlayer insulating film 290 may be formed on the insulation substrate 100. A trench 280T of the backside gate contact may be formed in the field region FR in FIG. 1. The trench 280T of the backside gate contact may penetrate the insulation substrate 100 and the first backside interlayer insulating film 290 to expose the protruding part 122b. The trench 280T of the backside gate contact may penetrate the insulation substrate 100 and the first backside interlayer insulating film 290 to expose the bottom surface of the first filling conductive film 122BS. The trench 280T of the backside gate contact may be formed by removing a portion of the insulation substrate 100 and a portion of the first backside interlayer insulating film 290 toward the field insulation layer 105 on the backside of the insulation substrate 100BS. The trench 280T of the backside gate contact may be formed by removing a portion of the field insulation layer 105 to expose the bottom surface of the first filling conductive film 122BS.

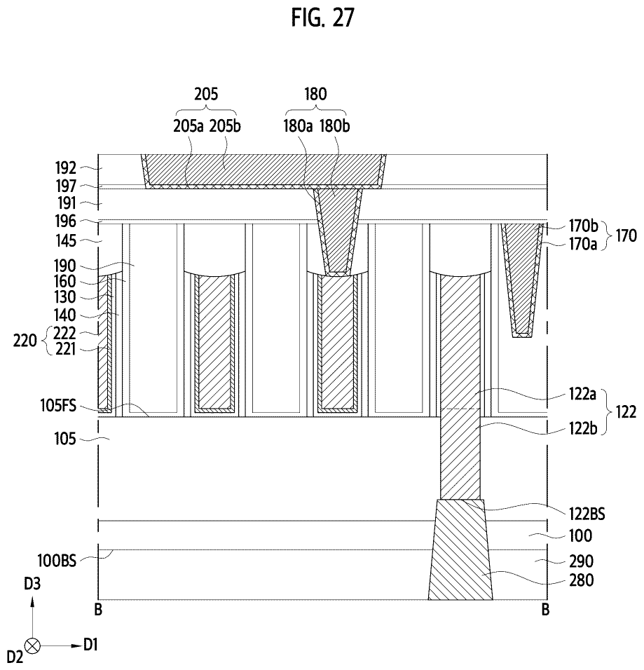

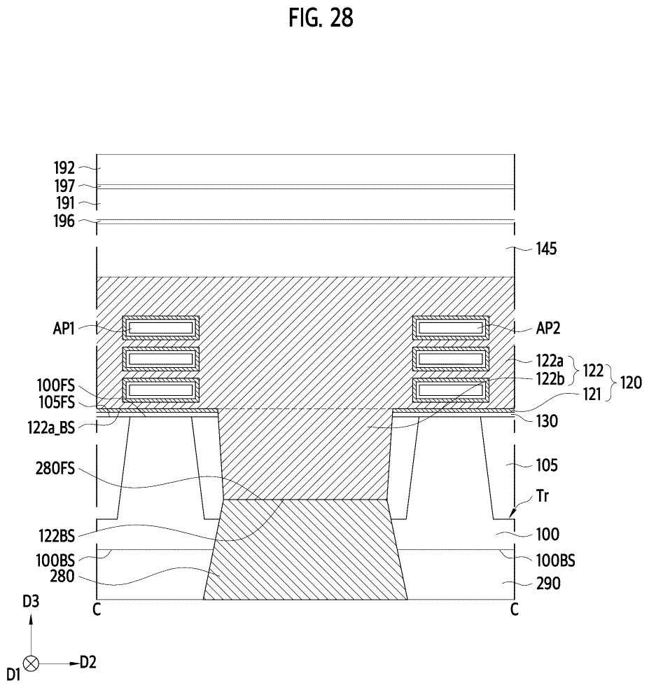

Further, referring to FIG. 27 and FIG. 28, the backside gate contact 280 may be formed. The backside gate contact 280 may fill the trench 280T in FIG. 25 and FIG. 26 of the backside gate contact. The backside gate contact 280 may be connected to the protruding part 122b exposed into the trench 280T of FIG. 25 and FIG. 26 of the backside gate contact in the field region FR of FIG. 1.

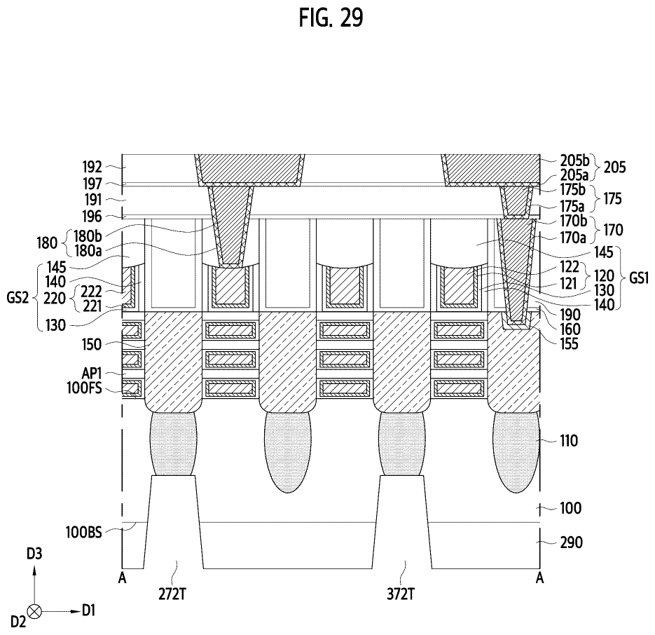

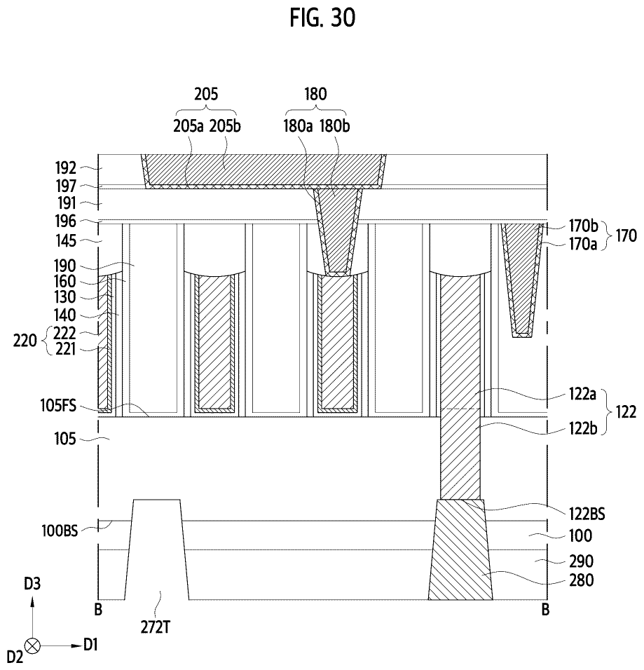

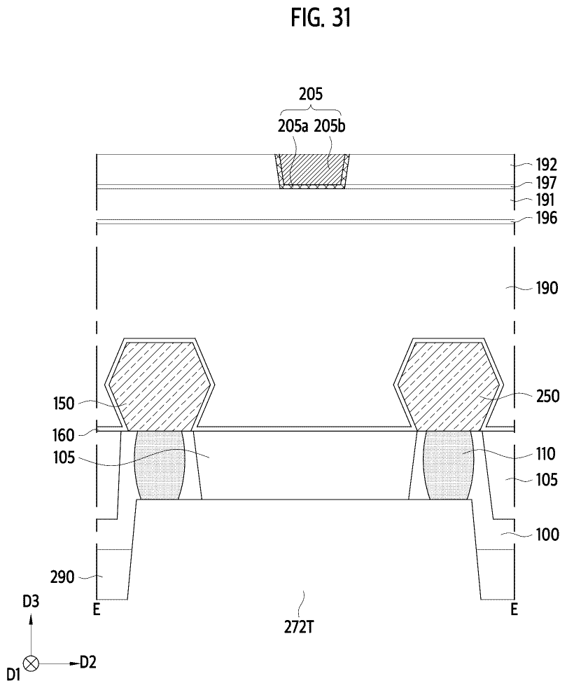

Further, referring to FIG. 29, FIG. 30, and FIG. 31, trenches 272T and 372T of the via connecting part may be formed. The trenches 272T and 372T of the via connecting part may be formed by removing a portion of the insulation substrate 100 and a portion of the first backside interlayer insulating film 290 toward the field insulation layer 105 on the backside of the insulation substrate 100BS. The trenches 272T and 372T of the via connecting part may be formed by removing a portion of the field insulation layer 105. The trenches 272T and 372T of the via connecting part may be formed by removing a portion of the field insulation layer 105 expose the supporter 110. In forming the trenches 272T and 372T of the via connecting part, a portion of the supporter 110 may be removed. The trenches 272T and 372T of the via connecting part may expose a width of the supporter 110. The trenches 272T and 372T of the via connecting part may expose an entire width of an exposed portion of the supporter 110. The trenches 272T and 372T of the via connecting part may have a width in the first direction D1 that is greater than a width of the supporter 110 in the first direction.

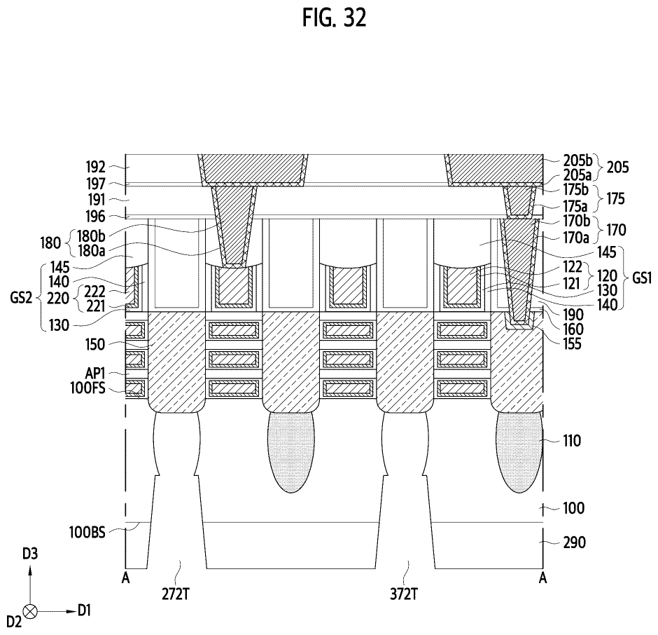

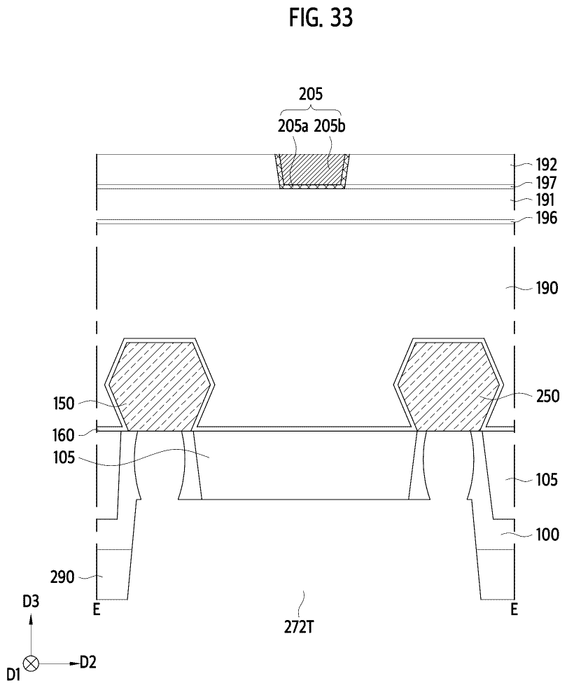

Further, referring to FIG. 32 and FIG. 33, the supporter 110 in FIG. 29 and FIG. 31 exposed by the trenches 272T and 372T of the via connecting part may be removed. The first source/drain pattern 150 and the second source/drain pattern 250 may be exposed through the trenches 272T and 372T of the via connecting part.

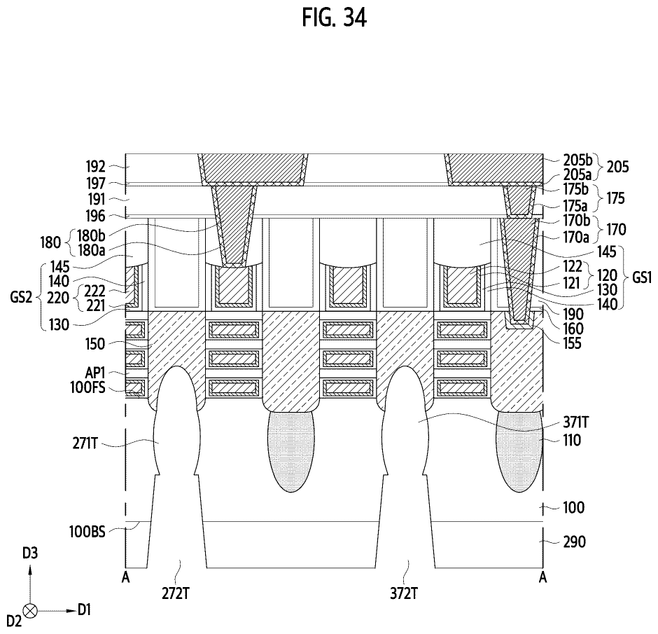

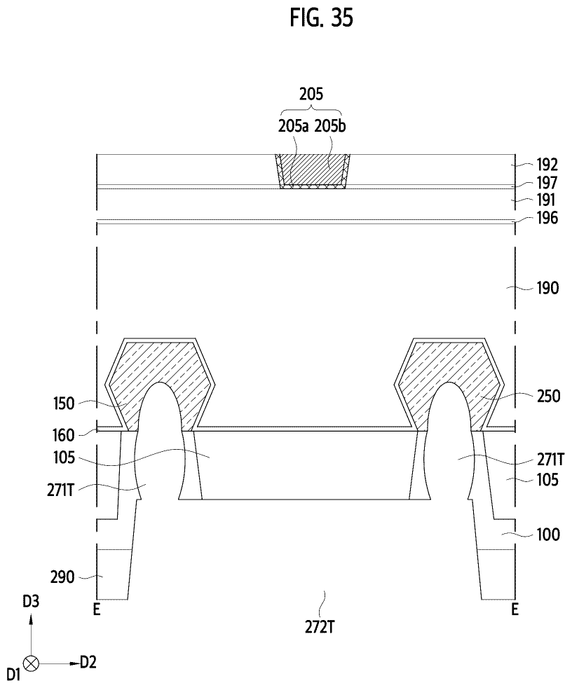

Further, referring to FIG. 34 and FIG. 35, a portion of the first source/drain pattern 150 and a portion of the second source/drain pattern 250 exposed by the trenches 272T and 372T of the via connecting part may be removed. The portion of the first source/drain pattern 150 and the portion of the second source/drain pattern 250 may be removed to form trenches 271T and 371T of the contact part. The first source/drain pattern 150 and the second source/drain pattern 250 may be exposed through the trenches 271T and 371T of the contact part.

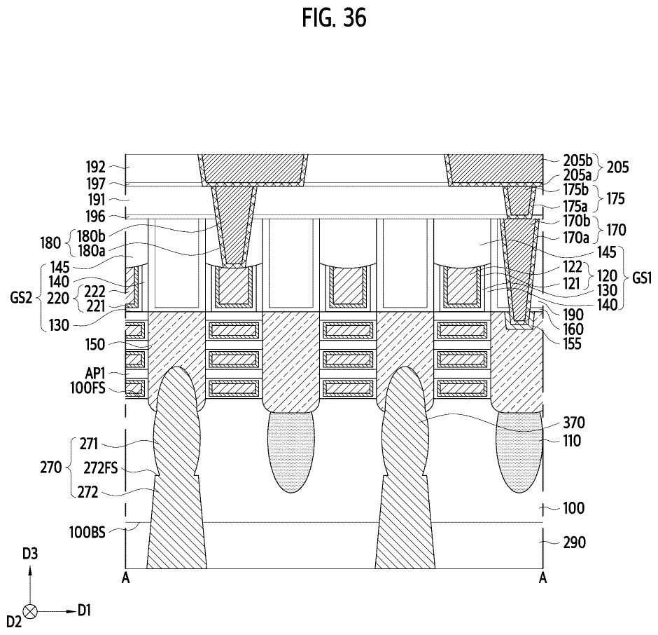

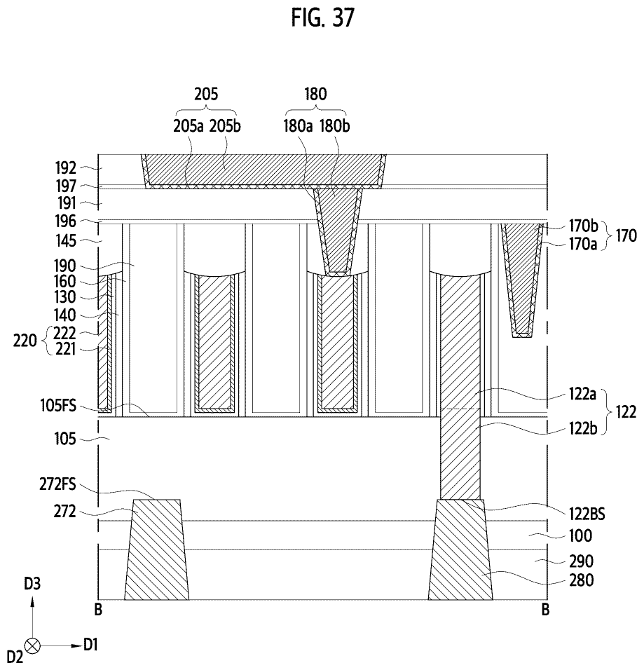

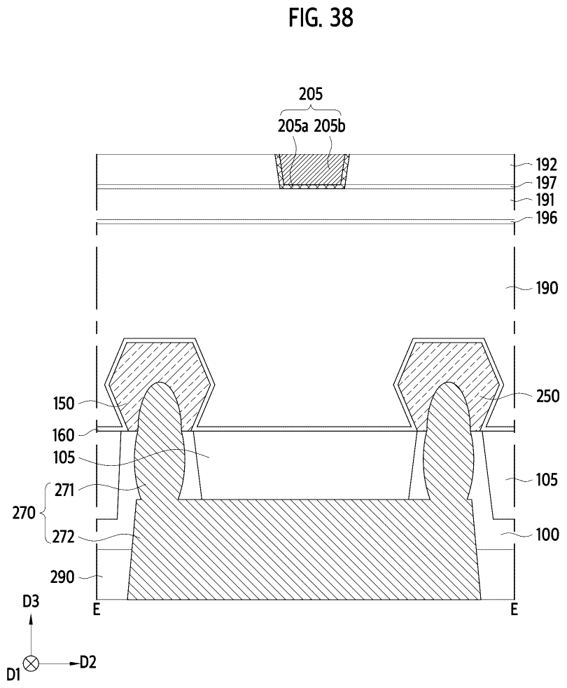

Further, referring to FIG. 36, FIG. 37, and FIG. 38, the first backside source/drain contact 270 and the second backside source/drain contact 370 may be formed to fill the trenches 272T and 372T of FIG. 34 and FIG. 35 of the via connecting part and the trenches 271T and 371T of FIGS. 34 and 35 of the contact part.

Further, referring to FIGS. 2 to 6, the first backside etching stopping layer 296, the second backside interlayer insulating film 291, the second backside etching stopping layer 297 and the third backside interlayer insulating film 292 may be formed. The backside wiring via 275 may be formed, which may be connected to the first backside source/drain contact 270, the second backside source/drain contact 370, and the backside gate contact 280. The first backside wiring line 310 and the second backside wiring line 320 may be formed on the backside wiring via 275. The first backside wiring line 310 may be formed in the field region FR in FIG. 1.

In the description, various embodiments of the present disclosure are described in detail. However, it will be apparent to those with average knowledge in the technical field that scope of rights of this disclosure is not limited thereto, and various modifications and variations are possible without departing from the technical spirit of the present disclosure as set forth in the claims. Further, example embodiments may be implemented with some elements deleted, and each example embodiment may be implemented in combination with each other.

What is claimed is:

1. A semiconductor device comprising:
an insulation substrate that comprises a first activation region extending in a first direction, a second activation region extending in the first direction and spaced apart from the first activation region in a second direction intersecting the first direction, and a field region disposed between the first activation region and the second activation region;
a field insulation layer disposed on the insulation substrate in the field region;
a first source/drain pattern that is disposed on a frontside of the insulation substrate in the first activation region;
a first gate electrode that is adjacent to the first source/drain pattern in the first direction and extending in the second direction; and
a backside gate contact that is disposed in the field region, and connected to the first gate electrode by penetrating the insulation substrate from a backside of the insulation substrate,
wherein the first gate electrode comprises a first filling conductive film, and a first electrode layer surrounding at least a portion of the first filling conductive film,
wherein the first filling conductive film comprises:
an extension part that extends in the second direction across the first activation region, the second activation region, and the field region on the frontside of the insulation substrate; and
a protruding part that is connected to the backside gate contact, and protruding from the extension part in a direction toward the insulation substrate,
wherein the first electrode layer is disposed on at least a portion of the extension part,
wherein a side wall of the protruding part is exposed by the first electrode layer, and
wherein the field insulation layer surrounds the side wall of the protruding part.

2. The semiconductor device of claim 1, further comprising a backside source/drain contact that is connected to the first source/drain pattern by penetrating the insulation substrate from the backside of the insulation substrate.

3. The semiconductor device of claim 2, wherein the backside source/drain contact comprises:
a via connecting part penetrating the backside of the insulation substrate; and
a contact part disposed on the via connecting part, and in contact with the first source/drain pattern,
wherein, relative to the backside of the insulation substrate, a bottom surface of the protruding part in contact with the backside gate contact is coplanar with or higher than a frontside of the via connecting part in contact with the contact part.

4. The semiconductor device of claim 3, wherein the via connecting part extends in the second direction across the first activation region, the second activation region, and the field region.

5. The semiconductor device of claim 1, further comprising a first backside wiring line that is disposed on the backside of the insulation substrate and connected to the backside gate contact in the field region.

6. The semiconductor device of claim 1, wherein, in the field region, the extension part has a width that is equal to a width of the protruding part in the first direction.

7. The semiconductor device of claim 6, wherein the first electrode layer overlaps the extension part in the first activation region and the second activation region in the first direction, and does not overlap the extension part in the field region in the first direction.

8. The semiconductor device of claim 1, wherein the backside gate contact has a width that is greater than the width of the protruding part in the first direction.

9. The semiconductor device of claim 1, wherein the backside gate contact in contact with the protruding part has a frontside with a width that is smaller than or equal to a width of a bottom surface of the protruding part in contact with the backside gate contact.

10. The semiconductor device of claim 1, further comprising a frontside source/drain contact that is disposed on the frontside of the insulation substrate, and is connected to the first source/drain pattern closest to the first gate electrode in the first direction.

11. The semiconductor device of claim 10, further comprising a second source/drain pattern that is disposed on the frontside of the insulation substrate in the second activation region,
wherein the frontside source/drain contact connects the first source/drain pattern and the second source/drain pattern.

12. The semiconductor device of claim 1, further comprising:
a second gate electrode that is adjacent to the first gate electrode in the first direction, and extending in the second direction; and
a frontside gate contact that is disposed on the frontside of the insulation substrate, and is connected to the second gate electrode,
wherein the second gate electrode comprises a second filling conductive film and a second electrode layer surrounding at least a portion of the second filling conductive film in the field region,
wherein the second electrode layer covers a bottom surface of the second filling conductive film, and
wherein the protruding part penetrates the first electrode layer in a third direction intersecting the first direction and the second direction.

13. The semiconductor device of claim 12, wherein the bottom surface of the second filling conductive film is disposed on a level that is above the bottom surface of the first filling conductive film relative to the backside of the insulation substrate.

14. The semiconductor device of claim 1, wherein the first activation region comprises a plurality of sheet patterns that are surrounded by the first gate electrode.

15. A semiconductor device comprising:
an insulation substrate that comprises a first activation region extending in a first direction, a second activation region formed by extending in the first direction and being spaced apart from the first activation region in a second direction intersecting the first direction and a field region disposed between the first activation region and the second activation region;
a first source/drain pattern that is disposed on a frontside of the insulation substrate in the first activation region;
a first gate electrode that is adjacent to the first source/drain pattern in the first direction and extending in the second direction;
a backside gate contact that is disposed in the field region, and connected to the first gate electrode by penetrating the insulation substrate from a backside of the insulation substrate;
a second source/drain pattern that is disposed on the frontside of the insulation substrate in the second activation region;
a first backside source/drain contact connecting a backside of the first source/drain pattern and a backside of the second source/drain pattern; and
a first backside wiring line that is disposed on the backside of the insulation substrate in the field region, and connected to the backside gate contact and the first backside source/drain contact,
wherein the first gate electrode has a backside that is disposed closer to the backside of the insulation substrate in the field region than in the first activation region and the second activation region.

16. The semiconductor device of claim 15, wherein the first gate electrode comprises a first filling conductive film, and a first electrode layer surrounding at least a portion of the first filling conductive film,
wherein the first electrode layer overlaps a backside of the first filling conductive film in the first activation region in a third direction intersecting the first direction and the second direction, and
wherein the first filling conductive film penetrates the first electrode layer in the third direction in the field region.

17. The semiconductor device of claim 16, further comprising a field insulation layer disposed on the insulation substrate in the field region,
wherein the first filling conductive film comprises:
an extension part that extends in the second direction across the first activation region and the second activation region on the frontside of the insulation substrate; and
a protruding part that is connected to the backside gate contact, and protruding from the extension part in a direction toward a backside of the insulation substrate,
wherein the first electrode layer overlaps the first filling conductive film in the first activation region in the first direction, and the protruding part penetrates the first electrode layer in the first direction in the field region, and
wherein the field insulation layer is in direct contact with the protruding part.

18. The semiconductor device of claim 15, further comprising:
a second backside source/drain contact that is connected to the backside of the first source/drain pattern; and
a second backside wiring line that is disposed on the backside of the insulation substrate in the first activation region, and is connected to the second backside source/drain contact.

19. The semiconductor device of claim 15, further comprising a frontside source/drain contact that is disposed on the frontside of the insulation substrate, and is connected to the first source/drain pattern closest to the first gate electrode in the first direction.

20. A semiconductor device comprising:
an insulation substrate that comprises a plurality of sheet patterns extending in a first direction, the insulation substrate comprising a first activation region and a second activation region that are spaced apart from each other in a second direction intersecting with the first direction, and a field region disposed between the first activation region and the second activation region;
a field insulation layer disposed on the insulating substrate in the field region;
a first source/drain pattern that is disposed on a frontside of the insulation substrate, and connected to the plurality of sheet patterns in the first activation region;
a first gate electrode that is spaced apart from the first source/drain pattern in the first direction and extending in the second direction;
a backside gate contact connected to the first gate electrode within the field insulation layer and penetrating the insulation substrate from a backside of the insulation substrate;
a first backside source/drain contact that is connected to the first source/drain pattern by penetrating the insulation substrate from the backside of the insulation substrate, and extending in the second direction across the first activation region and the second activation region; and
a first backside wiring line disposed in the field region and extending in the first direction on the backside of the insulation substrate, and connected to the backside gate contact and the first backside source/drain contact,
wherein the first gate electrode comprises a first filling conductive film and a first electrode layer surrounding at least a portion of the first filling conductive film,
wherein the first filling conductive film comprises:
an extension part that extends in the second direction across the first activation region, the second activation region, and the field region on the frontside of the insulation substrate; and
a protruding part that is connected to the backside gate contact in the field region, and protruding from the extension part toward the field insulation layer,
wherein the protruding part penetrates the first electrode layer on the field insulation layer,
wherein the first electrode layer surrounds at least a portion of the extension part, and the protruding part penetrates the first electrode layer in a third direction perpendicular to the first direction and the second direction, and
wherein the field insulation layer surrounds a side wall of the protruding part.
